(19) United States
(12) Patent Application Publication
(10) Pub. No.: US 2026/0231627 A1
(43) Pub. Date: Aug. 6, 2026

(54) CONTACT ELECTRODE OF DISPLAY DEVICE, ELECTRONIC DEVICE INCLUDING THE SAME AND METHOD OF PROVIDING THE SAME

(71) Applicant: Samsung Display Co., LTD., Yongin-si (KR)

(72) Inventors: BYOUNG KWON CHOO, Yongin-si (KR); BYUNG SOO SO, Yongin-si (KR); WOOJIN CHO, Yongin-si (KR); Sukyeong Shin, Yongin-si (KR)

(21) Appl. No.: 19/312,806

(22) Filed: Aug. 28, 2025

(30) Foreign Application Priority Data
Feb. 3, 2025 (KR) 10-2025-0012848

(51) Int. Cl. H10K 59/123; H10K 59/12

(52) U.S. Cl. CPC H10K 59/123; H10K 59/1201

(57) ABSTRACT

A display device includes a first insulating layer on a substrate, the first insulating layer including a first contact hole, a first contact hole including a first portion filling the first contact hole a second portion located on the first portion, a second insulating layer covering the second portion of the first contact electrode, and a light-emitting element on the second insulating layer.

The present application claims priority to Korean Patent Application No. 10-2025-0012848, filed on Feb. 3, 2025, and all the benefits accruing therefrom under 35 U.S.C. § 119, the entire content of which is incorporated by reference herein.

### BACKGROUND

### 1. Field

The present disclosure relates to a display device, a method of manufacturing (or providing) the display device, and an electronic device including the display device. More particularly, the present disclosure relates to a display device providing visual information, a method of manufacturing (or providing) the display device, and an electronic device including the display device.

### 2. Description of the Related Art

A display device is a device which displays an image for providing visual information to a user. Among display devices, an organic light-emitting diode display device has attracted attention.

The display device may include a contact electrode (a connection electrode or source/drain electrode). The contact electrode may be formed (or provided) by removing a portion of an electrode layer through a wet etching process using a photoresist pattern.

### SUMMARY

In a method of manufacturing (or providing) layers of a display device and/or an electronic device, when an electrode material layer is etched through the wet etching process, isotropic etching may be performed to remove a portion of the electrode material layer located under the photoresist pattern, resulting in skew, undercut, and/or the like. If design margin is increased in consideration of such skew and undercut, it may be difficult to implement a high-resolution display device.

Embodiments of the present disclosure provide a display device with improved quality.

Embodiments of the present disclosure provide a method of manufacturing the display device.

Embodiments of the present disclosure provide an electronic device including the display device.

A display device according to one or more embodiments includes a first insulating layer on a substrate, the first insulating layer including a first contact hole, a first contact electrode including a first portion filling the first contact hole a second portion located on the first portion, a second insulating layer covering the second portion of the first contact electrode, and a light-emitting element on the second insulating layer.

In one or more embodiments, the second portion may have a width which decreases as a distance between the first portion and the second portion increases.

In one or more embodiments, the first portion of the first contact electrode and the second portion of the first contact electrode may be in direct contact with each other.

In one or more embodiments, at least a portion of a side surface of the second portion of the first contact electrode may include a curved surface.

In one or more embodiments, a width of an upper surface of the second portion of the first contact electrode may be smaller than a width of the first contact hole.

In one or more embodiments, a width of the first portion of the first contact electrode may increase as a distance between the first portion and the second portion decreases.

In one or more embodiments, the display device may further include a seed layer filling the first contact hole and covering a side surface of the first contact electrode and a lower surface of the first contact electrode.

In one or more embodiments, the seed layer may include a first layer having a thickness equal to or greater than about 100 angstroms and equal to or less than about 200 angstroms and a second layer located on the first layer and having a thickness equal to or greater than about 300 angstroms and equal to or less than about 3000 angstroms.

In one or more embodiments, the first contact electrode may include at least one selected from bis-(3-sulfopropyl) disulfide (“SPS”), mercaptopropanesulfonic acid (“MPS”), and 3-N, N-dimethylaminodithiocarbamoyl-1-propanesulfonic acid (“DPS”).

In one or more embodiments, the first insulating layer may further include a second contact hole.

In one or more embodiments, the display device may further include a second contact electrode including a first portion filling the second contact hole and a second portion having a width decreasing as a distance between the first portion filling the second contact hole and the second portion of the second contact electrode increases.

In one or more embodiments, the second insulating layer may include a third contact hole exposing at least a portion of the second portion of the second contact electrode.

In one or more embodiments, the display device may further include a connection electrode including a first portion filling the third contact hole and a second portion connected to the light-emitting element and having a width which decreases as a distance between the light-emitting element and the second portion of the connection electrode decreases.

In one or more embodiments, the display device may further include an active pattern located on the substrate.

In one or more embodiments, the first insulating layer may cover the active pattern, and the first contact hole exposes at least a portion of the active pattern.

A method of manufacturing a display device according to one or more embodiments includes forming a first insulating layer including a contact hole on a substrate, forming an electrode layer located on the first insulating layer and filling the contact hole, forming a photoresist pattern on the electrode layer, removing at least a portion of the electrode layer to form a contact electrode, forming a second insulating layer covering at least a portion of the contact electrode, and forming a light-emitting element on the second insulating layer.

In one or more embodiments, the forming of the electrode layer may be performed through an electroplating process.

In one or more embodiments, the electroplating process may be performed using a copper plating solution, and the copper plating solution may include an aqueous electrolyte solution, an accelerator, and a suppressor.

In one or more embodiments, the accelerator may be located in a portion overlapping the contact hole in a plan view, and the suppressor may be located in a portion spaced apart from the contact hole in the plan view.

In one or more embodiments, the method may further include forming a preliminary seed layer located on the first insulating layer and filling the contact hole.

In one or more embodiments, at least a portion of the preliminary seed layer may be removed through a wet etching process to form a seed layer.

In one or more embodiments, the removing of at least the portion of the electrode layer may include removing at least a portion of the electrode layer located on the first insulating layer through a wet etching process.

In one or more embodiments, the method may further include forming an active pattern on the substrate.

In one or more embodiments, the first insulating layer may cover the active pattern, and the contact hole exposes at least a portion of the active pattern.

An electronic device according to one or more embodiments includes a first insulating layer on a substrate, the first insulating layer including a first contact hole, a first contact electrode including a first portion filling the first contact hole a second portion located on the first portion, a second insulating layer covering the second portion of the first contact electrode, a light-emitting element on the second insulating layer, and a memory configured to store data information.

A display device according to one or more embodiments may include a first insulating layer on a substrate, the first insulating layer including a first contact hole, a first contact electrode including a first portion filling the first contact hole a second portion located on the first portion, a second insulating layer covering the second portion of the first contact electrode, and a light-emitting element on the second insulating layer.

The first portion of the first contact electrode may be formed through an electroplating process. The second portion of the first contact electrode may be formed through the electroplating process and a wet etching process. Accordingly, the first contact electrode suitable for a high-resolution display device may be formed with reduced manufacturing cost and manufacturing time.

### BRIEF DESCRIPTION OF THE DRAWINGS

Illustrative, non-limiting embodiments will be more clearly understood from the following detailed description in conjunction with the accompanying drawings.

FIG. 1 is a plan view illustrating a display device according to one or more embodiments.

FIG. 2 is a cross-sectional view of the display device of FIG. 1 taken along line I-I′.

FIG. 3 is an enlarged cross-sectional view of an area A of FIG. 2.

FIG. 4 is an enlarged cross-sectional view of an area X of FIG. 3.

FIG. 5 is an enlarged cross-sectional view of an area B of FIG. 2.

FIGS. 6, 7, 8, 9, 10, 11, 12, 13, 14, 15, 16, 17, 18, 19, 20, 21, 22, 23, 24, 25, 26, 27, 28, and 29 are cross-sectional views illustrating a method of manufacturing the display device of FIG. 2.

FIG. 30 is a block diagram illustrating an electronic device according to embodiments.

FIG. 31 is a schematic diagram of an electronic device according to various embodiments.

### DETAILED DESCRIPTION

Hereinafter, display devices in accordance with embodiments will be described in more detail with reference to the accompanying drawings. The same reference numerals are used for the same components in the drawings, and redundant descriptions of the same components will be omitted. Within the Figures and the text of the disclosure, a reference number indicating a singular form of an element may also be used to reference a plurality of the element.

It will be understood that when an element is referred to as being related to another element such as being “on” another element, it can be directly on the other element or intervening elements may be present therebetween. In contrast, when an element is referred to as being related to another element such as “directly on” another element, there are no intervening elements present.

It will be understood that, although the terms “first,” “second,” “third” etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, “a first element,” “component,” “region,” “layer” or “section” discussed below could be termed a second element, component, region, layer or section without departing from the teachings herein.

The terminology used herein is for the purpose of describing particular embodiments only and is not intended to be limiting. As used herein, “a”, “an,” “the,” and “at least one” do not denote a limitation of quantity, and are intended to include both the singular and plural, unless the context clearly indicates otherwise. Thus, reference to “an” element in a claim followed by reference to “the” element is inclusive of one element and a plurality of the elements. For example, “an element” has the same meaning as “at least one element,” unless the context clearly indicates otherwise. “At least one” is not to be construed as limiting “a” or “an.” “Or” means “and/or.” As used herein, the term “and/or” includes any and all combinations of one or more of the associated listed items. It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

Furthermore, relative terms, such as “lower” or “bottom” and “upper” or “top,” may be used herein to describe one element's relationship to another element as illustrated in the Figures. It will be understood that relative terms are intended to encompass different orientations of the device in addition to the orientation depicted in the Figures. For example, if the device in one of the figures is turned over, elements described as being on the “lower” side of other elements would then be oriented on “upper” sides of the other elements. The term “lower,” can therefore, encompasses both an orientation of “lower” and “upper,” depending on the particular orientation of the figure. Similarly, if the device in one of the figures is turned over, elements described as “below” or “beneath” other elements would then be oriented “above” the other elements. The terms “below” or “beneath” can, therefore, encompass both an orientation of above and below.

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” can mean within one or more standard deviations, or within ±30%, 20%, 10% or 5% of the stated value.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

Embodiments are described herein with reference to cross section illustrations that are schematic illustrations of idealized embodiments. As such, variations from the shapes of the illustrations as a result, for example, of manufacturing techniques and/or tolerances, are to be expected. Thus, embodiments described herein should not be construed as limited to the particular shapes of regions as illustrated herein but are to include deviations in shapes that result, for example, from manufacturing. For example, a region illustrated or described as flat may, typically, have rough and/or nonlinear features. Moreover, sharp angles that are illustrated may be rounded. Thus, the regions illustrated in the figures are schematic in nature and their shapes are not intended to illustrate the precise shape of a region and are not intended to limit the scope of the present claims.

As being in a same layer, elements may be formed in a same process and/or include a same material as each other, elements may be respective portions of a same material layer, elements may be on a same layer by forming an interface with a same underlying or overlying layer, elements may be coplanar with each other or be disposed in a same thickness, etc., without being limited thereto.

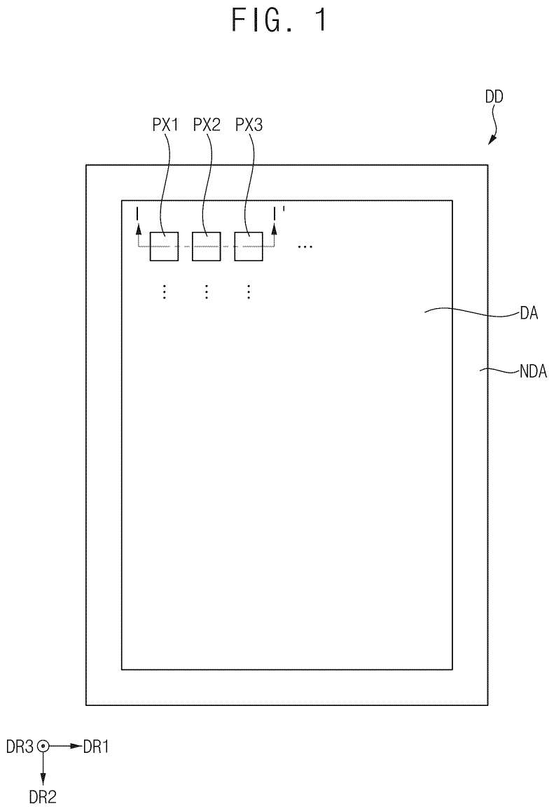

FIG. 1 is a plan view illustrating a display device DD according to one or more embodiments.

Referring to FIG. 1, the display device DD according to one or more embodiments may include a display area DA and a non-display area NDA which is adjacent to the display area DA.

The display area DA may be an area (e.g., a planar area) which generates light and/or displays an image by controlling transmittance of light provided from an external light source. A plurality of pixel areas may be arranged in the display area DA. For example, the display area DA may include a first pixel area PX1, a second pixel area PX2, and a third pixel area PX3. Each of the plurality of pixel areas may emit light. For example, the first pixel area PX1 may emit first light, the second pixel area PX2 may emit second light, and the third pixel area PX3 may emit third light. In one or more embodiments, the first light may be red light, the second light may be green light, and the third light may be blue light. However, this disclosure is not necessarily limited thereto. For example, the first pixel area PX1, the second pixel area PX2, and the third pixel area PX3 may be configured to emit yellow, cyan, and magenta light.

The plurality of pixel areas may be generally arranged across the display area DA. Accordingly, the display area DA may display an image. In one or more embodiments, the plurality of pixel areas may be repeatedly arranged along a first direction DR1 and a second direction DR2 which crosses the first direction DR1. For example, the second pixel area PX2 may be spaced apart from the first pixel area PX1 in the first direction DR1, and the third pixel area PX3 may be spaced apart from the second pixel area PX2 in the first direction DR1.

The non-display area NDA may surround at least a portion of the display area DA. A driver may be located in the non-display area NDA. The driver may provide a signal or a voltage to the plurality of pixel areas. For example, the driver may include a data driver, a gate driver, and/or the like. The non-display area NDA may not display an image.

In one or more embodiments, the first direction DR1 and the second direction DR2 which crosses the first direction DR1 may be defined. For example, the second direction DR2 may be substantially perpendicular to the first direction DR1. However, this disclosure is not necessarily limited thereto, and the second direction DR2 may form an acute angle or an obtuse angle with the first direction DR1. In addition, a third direction DR3 crossing a plane formed by the first direction DR1 and the second direction DR2 crossing each other may be defined. For example, the third direction DR3 may be substantially perpendicular to the plane formed by the first direction DR1 and the second directions DR2. However, this disclosure is not necessarily limited thereto, and the third direction DR3 may form an acute angle or an obtuse angle with the plane formed by the first direction DR1 and the second direction DR2. A thickness of the display device DD and various components or layers thereof may be defined along the third direction DR3 (e.g., a thickness direction).

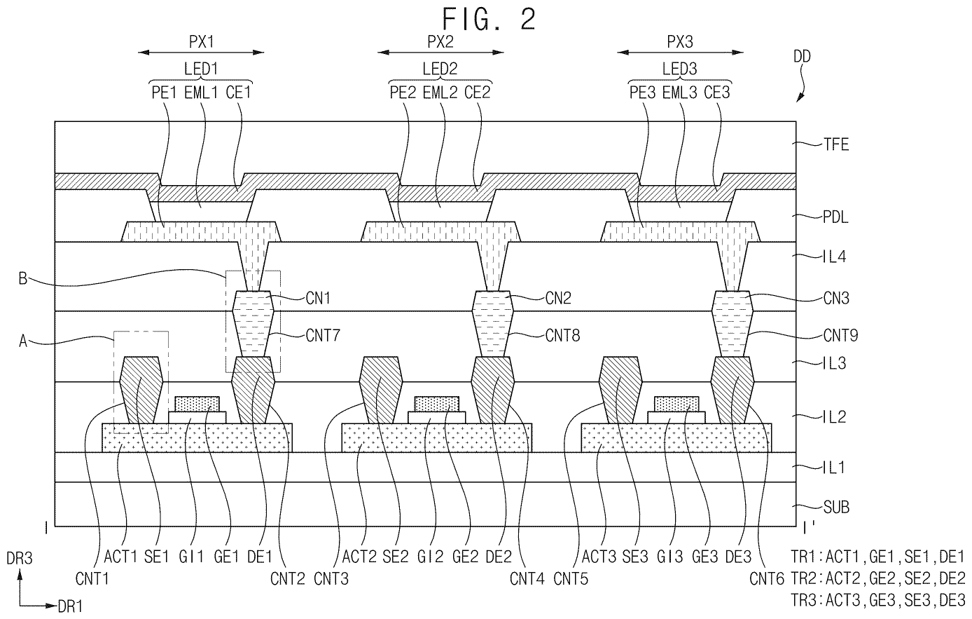

FIG. 2 is a cross-sectional view of the display device of FIG. 1 taken along line I-I′.

Referring to FIG. 2, the display device DD according to one or more embodiments may include a substrate SUB, a first insulating layer IL1, a second insulating layer IL2, a first transistor TR1, a second transistor TR2, a third transistor TR3, a first gate insulating layer GI1, a second gate insulating layer GI2, a third gate insulating layer GI3, a third insulating layer IL3, a first connection electrode CN1, a second connection electrode CN2, a third connection electrode CN3, a fourth insulating layer IL4, a first light-emitting element LED1, a second light-emitting element LED2, a third light-emitting element LED3, and an encapsulation layer TFE.

The first transistor TR1 may include a first active pattern ACT1, a first gate electrode GE1, a first contact electrode SE1, and a second contact electrode DE1. The second transistor TR2 may include a second active pattern ACT2, a second gate electrode GE2, a third contact electrode SE2, and a fourth contact electrode DE2. The third transistor TR3 may include a third active pattern ACT3, a third gate electrode GE3, a fifth contact electrode SE3, and a sixth contact electrode DE3.

The first light-emitting element LED1 may include a first pixel electrode PE1, a first light-emitting layer EML1, and a first common electrode CE1. The second light-emitting element LED2 may include a second pixel electrode PE2, a second light-emitting layer EML2, and a second common electrode CE2. The third light-emitting element LED3 may include a third pixel electrode PE3, a third light-emitting layer EML3, and a third common electrode CE3.

The substrate SUB may be a base of the display device DD and may define an overall planar shape and/or overall planar dimensions of the display device DD. The substrate SUB may include a transparent material or an opaque material. The substrate SUB may be formed of a transparent resin substrate. Example of the transparent resin substrate may include a polyimide substrate. In this case, the polyimide substrate may include a first organic layer, a first barrier layer, a second organic layer, and/or the like. In another embodiment, the substrate SUB may include a quartz substrate (e.g. a synthetic quartz substrate, a fluorine-doped quartz substrate), a calcium fluoride substrate, a soda lime glass substrate, a non-alkali glass substrate, and/or the like. These materials may be used alone or in combination with each other.

The first insulating layer IL1 may be located on the substrate SUB. The first insulating layer IL1 may prevent metal atoms or impurities from being diffused from the substrate SUB to each of the first transistor TR1, the second transistor TR2, the third transistor TR3, and/or the like. In addition, when a surface (e.g., upper surface) of the substrate SUB is not uniform, the first insulating layer IL1 may improve flatness of the surface of the substrate SUB. The first insulating layer IL1 may include inorganic materials such as silicon oxide (“SiOₓ”), silicon nitride (“SiNₓ”), silicon carbide (“SiCₓ”), silicon oxynitride (“SiOₓN_{y}”), silicon oxycarbide (“SiOₓC_{y}”), and/or the like. These materials may be used alone or in combination with each other.

The first active pattern ACT1, the second active pattern ACT2, and the third active pattern ACT3 within an active layer on the substrate SUB, may be located on the first insulating layer IL1. The first active pattern ACT1, the second active pattern ACT2, and the third active pattern ACT3 may be spaced apart from each other in a plan view, that is, in a planar direction of the substrate SUB. For example, as illustrated in FIG. 2, the second active pattern ACT2 may be spaced apart from the first active pattern ACT1 in the first direction DR1, and the third active pattern ACT3 may be spaced apart from the second active pattern ACT2 in the first direction DR1. The first active pattern ACT1 is located in a portion of the first pixel area PX1, the second active pattern ACT2 is located in a portion the second pixel area PX2, and the third active pattern ACT3 may be located in a portion of the third pixel area PX3, but this disclosure is not necessarily limited thereto.

Each of the first active pattern ACT1, the second active pattern ACT2, and the third active pattern ACT3 may include a first contact area, a second contact area, and a channel area located between the first contact area and the second contact area, in a direction along the active pattern. Each of the first active pattern ACT1, the second active pattern ACT2, and the third active pattern ACT3 may include an inorganic semiconductor (e.g., amorphous silicon semiconductor, polysilicon semiconductor, a metal oxide semiconductor,), an organic semiconductor, and/or the like. These materials may be used alone or in combination with each other. The metal oxide semiconductor may include a binary compound (“ABₓ”), a ternary compound (“ABₓC_{y}”), a quaternary compound (“ABₓC_{y}D_{z}”), and/or the like including indium (“In”), zinc (“Zn”), gallium (“Ga”), tin (“Sn”), titanium (“Ti”), aluminum (“Al”), hafnium (“Hf”), zirconium (“Zr”), magnesium (“Mg”), and/or the like. These materials may be used alone or in combination with each other. For example, the metal oxide semiconductor may include zinc oxide (“ZnOₓ”), gallium oxide (“GaOₓ”), tin oxide (“SnOₓ”), indium oxide (“InOₓ”), indium gallium oxide (“IGO”), indium zinc oxide (“IZO”), indium tin oxide (“ITO”), indium zinc tin oxide (“IZTO”), and indium gallium zinc oxide (“IGZO”). These materials may be used alone or in combination with each other.

The first gate insulating layer GI1 may be located on the first active pattern ACT1. The first gate insulating layer GI1 may at least partially overlap the channel area of the first active pattern ACT1 in the plan view. The second gate insulating layer GI2 may be located on the second active pattern ACT2. The second gate insulating layer GI2 may at least partially overlap the channel area of the second active pattern ACT2 in the plan view. The third gate insulating layer GI3 layer may be located on the third active pattern ACT3. The third gate insulating layer GI3 may at least partially overlap the channel area of the third active pattern ACT3 in the plan view. Each of the first gate insulating layer GI1, the second gate insulating layer GI2, and the third gate insulating layer GI3 may include inorganic materials such as silicon oxide (“SiOₓ”), silicon nitride (“SiNₓ”), silicon carbide (“SiCₓ”), silicon oxynitride (“SiOₓN_{y}”), silicon oxycarbide (“SiOₓC_{y}”), and/or the like. These materials may be used alone or in combination with each other.

The first gate electrode GE1 layer may be located on the first gate insulating layer GI1. The first gate electrode GE1 may at least partially overlap the first gate insulating layer GI1 in the plan view. For example, the first gate electrode GE1 may overlap the channel area of the first active pattern ACT1 in the plan view. The second gate electrode GE2 layer may be located on the second gate insulating layer GI2. The second gate electrode GE2 may at least partially overlap the second gate insulating layer GI2 in the plan view. For example, the second gate electrode GE2 may overlap the channel area of the second active pattern ACT2 in the plan view. The third gate electrode GE3 layer may be located on the third gate insulating layer GI3. The third gate electrode GE3 may at least partially overlap the third gate insulating layer GI3 in the plan view. For example, the third gate electrode GE3 may overlap the channel area of the third active pattern ACT3 in the plan view.

Each of the first gate electrode GE1, the second gate electrode GE2, and the third gate electrode GE3 may include a metal, an alloy, a metal nitride, a conductive metal oxide, a transparent conductive material, and/or the like. Examples of the metal may include silver (“Ag”), molybdenum (“Mo”), aluminum (“Al”), tungsten (“W”), copper (“Cu”), nickel (“Ni”), chromium (“Cr”), titanium (“Ti”), tantalum (“Ta”), platinum (“Pt”), scandium (“Sc”), and/or the like. These materials may be used alone or in combination with each other. Examples of the conductive metal oxide may include indium tin oxide, indium zinc oxide, and/or the like. These materials may be used alone or in combination with each other. In addition, examples of the metal nitride may include aluminum nitride (“AlNₓ”), tungsten nitride (“WNₓ”), chromium nitride (“CrNₓ”), and/or the like. These materials may be used alone or in combination with each other.

The second insulating layer IL2 may be located on the first insulating layer IL1. The second insulating layer IL2 may cover the first active pattern ACT1, the second active pattern ACT2, and the third active pattern ACT3. In addition, the second insulating layer IL2 may cover the first gate insulating layer GI1, the second gate insulating layer GI2, and the third gate insulating layer GI3. In addition, the second insulating layer IL2 may cover the first gate electrode GE1, the second gate electrode GE2, and the third gate electrode GE3.

In one or more embodiments, the second insulating layer IL2 may include lower contact holes defined therein such as a first contact hole CNT1, a second contact hole CNT2, a third contact hole CNT3, a fourth contact hole CNT4, a fifth contact hole CNT5 and a sixth contact hole CNT6. Each of the first contact hole CNT1, the second contact hole CNT2, the third contact hole CNT3, the fourth contact hole CNT4, the fifth contact hole CNT5, and the sixth contact hole CNT6 may be a portion obtained by removing a (material) portion of the second insulating layer IL2, such removal starting from an upper surface of the second insulating layer IL2. The contact holes may penetrate completely through a thickness of the second insulating layer IL2.

Each of the first contact hole CNT1 and the second contact hole CNT2 may expose at least a portion of the first active pattern ACT1 to outside the active layer. For example, each of the first contact hole CNT1 and the second contact hole CNT2 may expose a portion of an upper surface of the first active pattern ACT1. For example, the first contact hole CNT1 may expose the first contact area of the first active pattern ACT1, and the second contact hole CNT2 may expose the second contact area of the first active pattern ACT1.

Each of the third contact hole CNT3 and the fourth contact hole CNT4 may expose at least a portion of the second active pattern ACT2 to outside the active layer. For example, each of the third contact hole CNT3 and the fourth contact hole CNT4 may expose a portion of an upper surface of the second active pattern ACT2. For example, the third contact hole CNT3 may expose the first contact area of the second active pattern ACT2, and the fourth contact hole CNT4 may expose the second contact area of the second active pattern ACT2.

Each of the fifth contact hole CNT5 and the sixth contact hole CNT6 may expose at least a portion of the third active pattern ACT3 to outside the active layer. For example, each of the fifth contact hole CNT5 and the sixth contact hole CNT6 may expose a portion of an upper surface of the third active pattern ACT3. For example, the fifth contact hole CNT5 may expose the first contact area of the third active pattern ACT3, and the sixth contact hole CNT6 may expose the second contact area of the third active pattern ACT3.

The second insulating layer IL2 may include inorganic materials such as silicon oxide (“SiOₓ”), silicon nitride (“SiNₓ”), silicon carbide (“SiCₓ”), silicon oxynitride (“SiOₓN_{y}”), silicon oxycarbide (“SiOₓC_{y}”), and/or the like. These materials may be used alone or in combination with each other.

The first contact electrode SE1, the second contact electrode DE1, the third contact electrode SE2, the fourth contact electrode DE2, the fifth contact electrode SE3 and the sixth contact electrode DE3 may be located on the second insulating layer IL2 as respective patterns of an electrode layer or a conductive layer. The first contact electrode SE1, the second contact electrode DE1, the third contact electrode SE2, the fifth contact electrode SE3 and the sixth contact electrode DE3 may be spaced apart from each other in the plan view. For example, as illustrated in FIG. 2, the second contact electrode DE1 may be spaced apart from the first contact electrode SE1 in the first direction DR1, the third contact electrode SE2 may be spaced apart from the second contact electrode DE1 in the first direction DR1, the fourth contact electrode DE2 may be spaced apart from the third contact electrode SE2 in the first direction DR1, the fifth contact electrode SE3 may be spaced apart from the fourth contact electrode DE2 in the first direction DR1, and the sixth contact electrode DE3 may be spaced apart from the fifth contact electrode SE3 in the first direction DR1. The various contact electrodes described may be otherwise referred to as a transistor electrode.

The first contact electrode SE1 may fill the first contact hole CNT1. The first contact electrode SE1 may be connected (e.g., electrically) to the first contact area of the first active pattern ACT1, through the first contact hole CNT1. For example, the first contact electrode SE1 may be connected to the first contact area of the first active pattern ACT1 by filling the first contact hole CNT1.

The second contact electrode DE1 may fill the second contact hole CNT2. The second contact electrode DE1 may be connected to the second contact area of the first active pattern ACT1, through the second contact hole CNT2. For example, the second contact electrode DE1 may be connected to the second contact area of the first active pattern ACT1 by filling the second contact hole CNT2.

The third contact electrode SE2 may fill the third contact hole CNT3. The third contact electrode SE2 may be connected to the first contact area of the second active pattern ACT2, through the third contact hole CNT3. For example, the third contact electrode SE2 may be connected to the first contact area of the second active pattern ACT2 by filling the third contact hole CNT3.

The fourth contact electrode DE2 may fill the fourth contact hole CNT4. The fourth contact electrode DE2 may be connected to the second contact area of the second active pattern ACT2, through the fourth contact hole CNT4. For example, the fourth contact electrode DE2 may be connected to the second contact area of the second active pattern ACT2 by filling the fourth contact hole CNT4.

The fifth contact electrode SE3 may fill the fifth contact hole CNT5. The fifth contact electrode SE3 may be connected to the first contact area of the third active pattern ACT3, through the fifth contact hole CNT5. For example, the fifth contact electrode SE3 may be connected to the first contact area of the third active pattern ACT3 by filling the fifth contact hole CNT5.

The sixth contact electrode DE3 may fill the sixth contact hole CNT6. The sixth contact electrode DE3 may be connected to the second contact area of the third active pattern ACT3, through the sixth contact hole CNT6. For example, the sixth contact electrode DE3 may be connected to the second contact area of the third active pattern ACT3 by filling the sixth contact hole CNT6.

In one or more embodiments, each of the first contact electrode SE1, the second contact electrode DE1, the third contact electrode SE2, the fourth contact electrode DE2, the fifth contact electrode SE3 and the sixth contact electrode DE3 may include a metal, an alloy, a metal nitride, a conductive metal oxide, a transparent conductive material, and/or the like. Examples of the metal may include silver (“Ag”), molybdenum (“Mo”), aluminum (“Al”), tungsten (“W”), copper (“Cu”), nickel (“Ni”), chromium (“Cr”), titanium (“Ti”), tantalum (“Ta”), platinum (“Pt”), scandium (“Sc”), and/or the like. These materials may be used alone or in combination with each other. Examples of the conductive metal oxide may include indium tin oxide, indium zinc oxide, and/or the like. These materials may be used alone or in combination with each other. In addition, examples of the metal nitride may include aluminum nitride (“AlNₓ”), tungsten nitride (“WNₓ”), chromium nitride (“CrNₓ”), and/or the like. These materials may be used alone or in combination with each other. For example, each of the first contact electrode SE1, the second contact electrode DE1, the third contact electrode SE2, the fourth contact electrode DE2, the fifth contact electrode SE3, and the sixth contact electrode DE3 may include copper (“Cu”).

In one or more embodiments, each of the first contact electrode SE1, the second contact electrode DE1, the third contact electrode SE2, the fourth contact electrode DE2, the fifth contact electrode SE3, and the sixth contact electrode DE3 may further include bis-(3-sulfopropyl) disulfide (“SPS”), mercaptopropanesulfonic acid (“MPS”), 3-N, N-dimethylaminodithiocarbamoyl-1-propanesulfonic acid (“DPS”), and/or the like. These materials may be used alone or in combination with each other. In one or more embodiments, each of the first contact electrode SE1, the second contact electrode DE1, the third contact electrode SE2, the fourth contact electrode DE2, the fifth contact electrode SE3, and the sixth contact electrode DE3 may further include polyethylene oxide (“PEO”), polypropylene oxide (“PPO”), polyethylene glycol (“PEG”), polypropylene glycol (“PPG”), and/or the like. These materials may be used alone or in combination with each other.

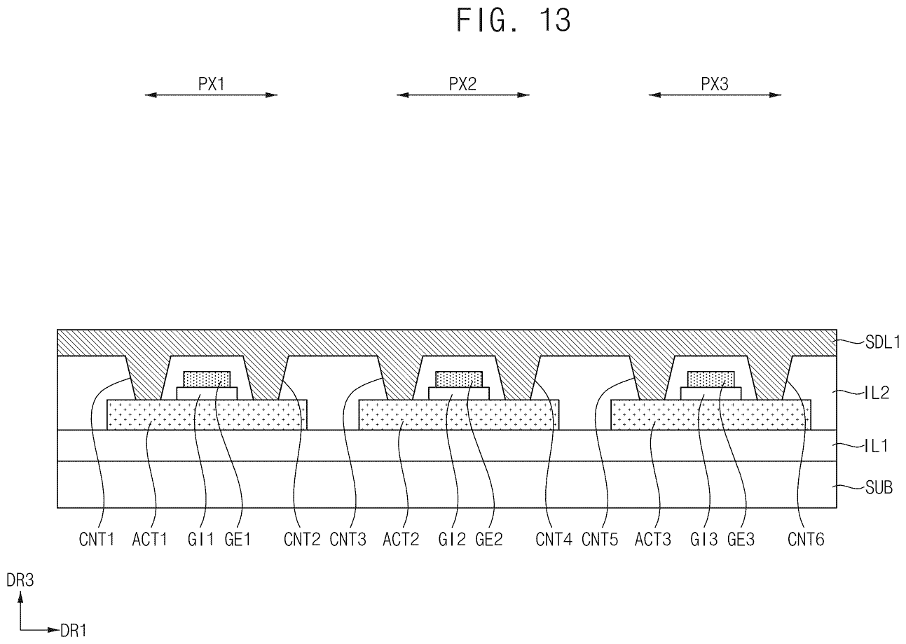

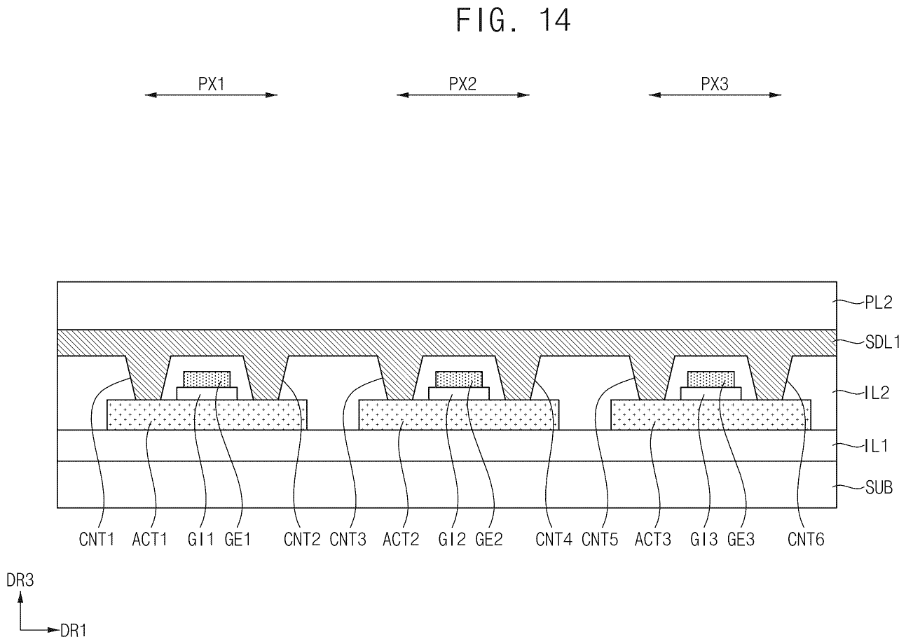

These material may be used since, as will be described later with reference to FIGS. 12 and 13, each of the first contact electrode SE1, the second contact electrode DE1, the third contact electrode SE2, the fourth contact electrode DE2, the fifth contact electrode SE3, and the sixth contact electrode DE3 is formed (or provided) by removing a portion a first electrode layer (e.g., a first electrode layer SDL1 of FIG. 13) formed through an electroplating process. That is, the first electrode layer may be an electroplated electrode layer. The electroplating process may be performed using a copper plating solution, and the copper plating solution may include an aqueous electrolyte solution, a first accelerator (e.g., a first accelerator AC1 of FIG. 12), and a first suppressor (e.g., a first suppressor SC1 of FIG. 12). The first accelerator may include bis-(3-sulfopropyl) disulfide (“SPS”), mercaptopropanesulfonic acid (“MPS”), 3-N, N-dimethylaminodithiocarbamoyl-1-propanesulfonic acid (“DPS”), and/or the like. These materials may be used alone or in combination with each other. The first suppressor may include polyethylene oxide (“PEO”), polypropylene oxide (“PPO”), polyethylene glycol (“PEG”), polypropylene glycol (“PPG”), and/or the like. These materials may be used alone or in combination with each other.

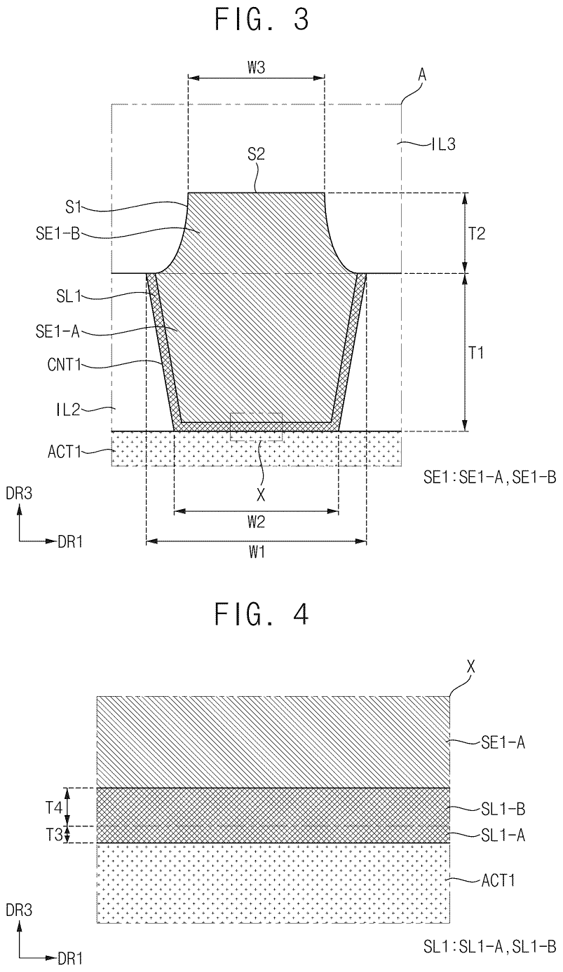

The third insulating layer IL3 may be located on the second insulating layer IL2. The third insulating layer IL3 may cover at least a portion of each of the first contact electrode SE1, the second contact electrode DE1, the third contact electrode SE2, the fourth contact electrode DE2, the fifth contact electrode SE3, and the sixth contact electrode DE3. For example, the third insulating layer IL3 may cover a portion of the first contact electrode SE1 which is located on the second insulating layer IL2. For example, the third insulating layer IL3 may cover a second portion (e.g., a second portion SE1-B of FIG. 3) of the first contact electrode SE1. In addition, the third insulating layer IL3 may cover a portion of the second contact electrode DE1 which is located on the second insulating layer IL2. In addition, the third insulating layer IL3 may cover a portion of the third contact electrode SE2 which is located on the second insulating layer IL2. In addition, the third insulating layer IL3 may cover a portion of the fourth contact electrode DE2 which is located on the second insulating layer IL2. In addition, the third insulating layer IL3 may cover a portion of the fifth contact electrode SE3 which is located on the second insulating layer IL2. In addition, the third insulating layer IL3 may cover a portion of the sixth contact electrode DE3 which is located on the second insulating layer IL2.

In one or more embodiments, the third insulating layer IL3 may include intermediate contact holes defined therein such as seventh contact hole CNT7, an eighth contact hole CNT8, and a ninth contact hole CNT9. Each of the seventh contact hole CNT7, the eighth contact hole CNT8, and the ninth contact hole CNT9 may be a portion obtained by removing a portion of the third insulating layer IL3 from an upper surface of the third insulating layer IL3.

The seventh contact hole CNT7 may expose at least a portion of the second contact electrode DE1 to outside the third insulating layer IL3. For example, the seventh contact hole CNT7 may expose a portion of an upper surface of the second contact electrode DE1. The eighth contact hole CNT8 may expose at least a portion of the fourth contact electrode DE2 to outside the third insulating layer IL3. For example, the eighth contact hole CNT8 may expose a portion of an upper surface of the fourth contact electrode DE2. The ninth contact hole CNT9 may expose at least a portion of the sixth contact electrode DE3 to outside the third insulating layer IL3. For example, the ninth contact hole CNT9 may expose a portion of an upper surface of the sixth contact electrode DE3.

The third insulating layer IL3 may include inorganic materials such as silicon oxide (“SiOₓ”), silicon nitride (“SiNₓ”), silicon carbide (“SiCₓ”), silicon oxynitride (“SiOₓN_{y}”), silicon oxycarbide (“SiOₓC_{y}”), and/or the like. These materials may be used alone or in combination with each other.

The first connection electrode CN1, the second connection electrode CN2, and the third connection electrode CN3 within a connection electrode layer may be located on the third insulating layer IL3. The first connection electrode CN1, the second connection electrode CN2, and the third connection electrode CN3 may be spaced apart from each other in the plan view. For example, as illustrated in FIG. 2, the second connection electrode CN2 may be spaced apart from the first connection electrode CN1 in the first direction DR1, and the third connection electrode CN3 may be spaced apart from the second connection electrode CN2 in the first direction DR1. The various connection electrodes may be otherwise referred to as a connection contact electrode.

The first connection electrode CN1 may fill the seventh contact hole CNT7. The first connection electrode CN1 may be connected to the second contact electrode DE1 through the seventh contact hole CNT7. For example, the first connection electrode CN1 may be electrically connected to an upper surface of the second contact electrode DE1 by filling the seventh contact hole CNT7.

The second connection electrode CN2 may fill the eighth contact hole CNT8. The second connection electrode CN2 may be connected to the fourth contact electrode DE2 through the eighth contact hole CNT8. For example, the second connection electrode CN2 may be electrically connected to an upper surface of the fourth contact electrode DE2 by filling the eighth contact hole CNT8.

The third connection electrode CN3 may fill the ninth contact hole CNT9. The third connection electrode CN3 may be connected to the sixth contact electrode DE3 through the ninth contact hole CNT9. For example, the third connection electrode CN3 may be electrically connected to an upper surface of the sixth contact electrode DE3 by filling the ninth contact hole CNT9.

In one or more embodiments, each of the first connection electrode CN1, the second connection electrode CN2, and the third connection electrode CN3 may include a metal, an alloy, a metal nitride, a conductive metal oxide, a transparent conductive material, and/or the like. Examples of the metal may include silver (“Ag”), molybdenum (“Mo”), aluminum (“Al”), tungsten (“W”), copper (“Cu”), nickel (“Ni”), chromium (“Cr”), titanium (“Ti”), tantalum (“Ta”), platinum (“Pt”), scandium (“Sc”), and/or the like. These materials may be used alone or in combination with each other. Examples of the conductive metal oxide may include indium tin oxide, indium zinc oxide, and/or the like. These materials may be used alone or in combination with each other. In addition, examples of the metal nitride may include aluminum nitride (“AlNₓ”), tungsten nitride (“WNₓ”), chromium nitride (“CrNₓ”), and/or the like. These materials may be used alone or in combination with each other. For example, each of the first connection electrode CN1, the second connection electrode CN2, and the third connection electrode CN3 may include copper (“Cu”).

In one or more embodiments, each of the first connection electrode CN1, the second connection electrode CN2, and the third connection electrode CN3 may further include bis-(3-sulfopropyl) disulfide (“SPS”), mercaptopropanesulfonic acid (“MPS”), 3-N, N-dimethylaminodithiocarbamoyl-1-propanesulfonic acid (“DPS”), and/or the like. These materials may be used alone or in combination with each other. In one or more embodiments, each of the first connection electrode CN1, the second connection electrode CN2, and the third connection electrode CN3 may further include polyethylene oxide (“PEO”), polypropylene oxide (“PPO”), polyethylene glycol (“PEG”), polypropylene glycol (“PPG”), and/or the like. These materials may be used alone or in combination with each other.

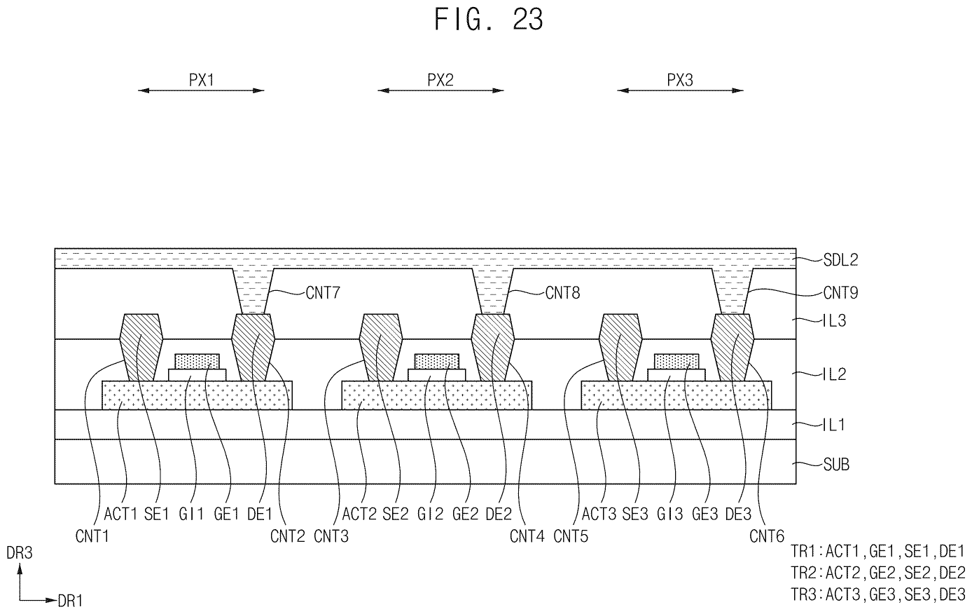

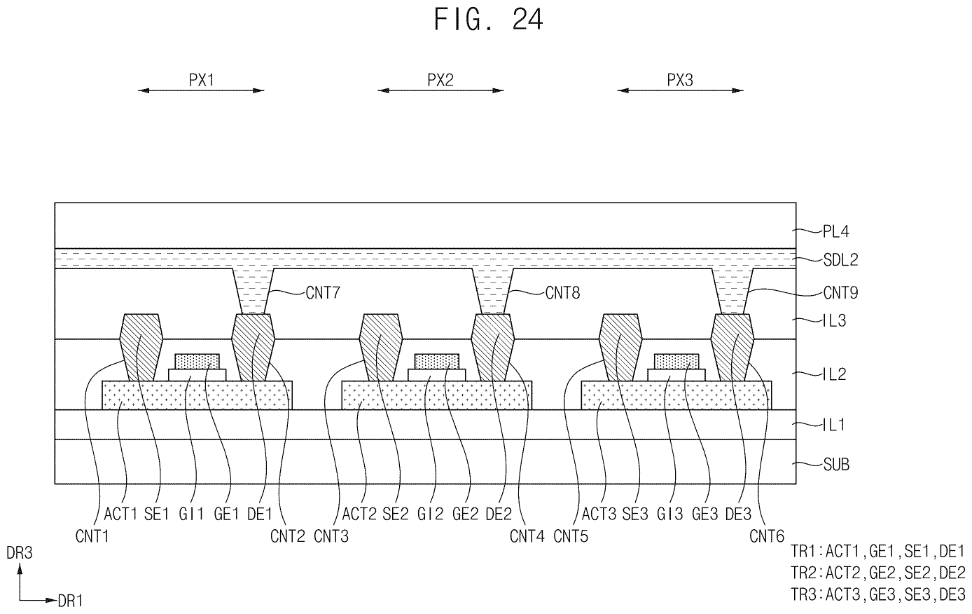

These materials may be since, as will be described later with reference to FIGS. 22 and 23, each of the first connection electrode CN1, the second connection electrode CN2, and the third connection electrode CN3 is formed by removing a portion a second electrode layer (e.g., a second electrode layer SDL2 of FIG. 23) formed through an electroplating process. That is, the second electrode layer may be an electroplated electrode layer. The electroplating process may be performed using a copper plating solution, and the copper plating solution may include an aqueous electrolyte solution, a second accelerator (e.g., a second accelerator AC2 of FIG. 22), and a second suppressor (e.g., a second suppressor SC2 of FIG. 22). The second accelerator may include bis-(3-sulfopropyl) disulfide (“SPS”), mercaptopropanesulfonic acid (“MPS”), 3-N, N-dimethylaminodithiocarbamoyl-1-propanesulfonic acid (“DPS”), and/or the like. These materials may be used alone or in combination with each other. The second suppressor may include polyethylene oxide (“PEO”), polypropylene oxide (“PPO”), polyethylene glycol (“PEG”), polypropylene glycol (“PPG”), and/or the like. These materials may be used alone or in combination with each other.

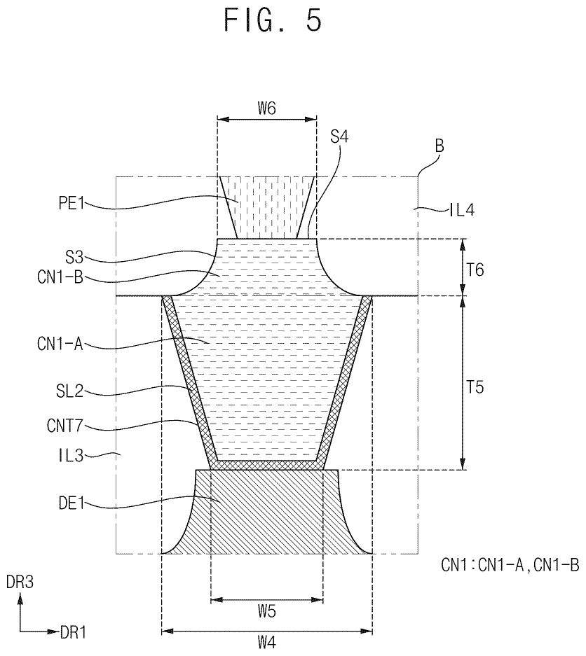

The fourth insulating layer IL4 may be located on the third insulating layer IL3. The fourth insulating layer IL4 may cover at least a portion of each of the first connection electrode CN1, the second connection electrode CN2, and the third connection electrode CN3. For example, the fourth insulating layer IL4 may cover a portion of the first connection electrode CN1 which is located on the third insulating layer IL3. For example, the fourth insulating layer IL4 may cover a second portion (e.g., a second portion CN1-B of FIG. 5) of a first connection electrode CN1. In addition, the fourth insulating layer IL4 may cover a portion of the second connection electrode CN2 which is located on the third insulating layer IL3. In addition, the fourth insulating layer IL4 may cover a portion of the third connection electrode CN3 which is located on the third insulating layer IL3. The fourth insulating layer IL4 may include an organic material such as phenolic resin, polyacrylates resin, polyimides resin, polyamides resin, siloxane resin, epoxy resin, and/or the like. These materials may be used alone or in combination with each other.

The first light-emitting element LED1, the second light-emitting element LED2, and the third light-emitting element LED3 of a light-emitting element layer may be located on the fourth insulating layer IL4. The first light-emitting element LED1 may be located in the first pixel area PX1, the second light-emitting element LED2 may be located in the second pixel area PX2, and the third light-emitting element LED3 may be located in the third pixel area PX3.

The first pixel electrode PE1 may be located on the fourth insulating layer IL4. The first pixel electrode PE1 may be located in the first pixel area PX1. The first pixel electrode PE1 may be connected to the first connection electrode CN1 through a contact hole included in the fourth insulating layer IL4. For example, the first pixel electrode PE1 may be electrically connected to a second portion (e.g., a second portion CN1-B of FIG. 5) of the first connection electrode CN1 through a contact hole included in the fourth insulating layer IL4.

The second pixel electrode PE2 may be located on the fourth insulating layer IL4. The second pixel electrode PE2 may be located in the second pixel area PX2. The second pixel electrode PE2 may be connected to the second connection electrode CN2 through a contact hole included in the fourth insulating layer IL4.

The third pixel electrode PE3 may be located on the fourth insulating layer IL4. The third pixel electrode PE3 may be located in the third pixel area PX3. The third pixel electrode PE3 may be connected to the third connection electrode CN3 through a contact hole included in the fourth insulating layer IL4.

One or more of the first insulating layer IL1, the second insulating layer IL2, the third insulating layer IL3 and the fourth insulating layer IL4 may be referred to as “an insulating layer.”

The first pixel electrode PE1 may be an anode electrode of the first light-emitting element LED1, the second pixel electrode PE2 may be an anode electrode of the second light-emitting element LED2, and the third pixel electrode PE3 may be an anode electrode of the third light-emitting element LED3. Each of the first pixel electrode PE1, the second pixel electrode PE2, and the third pixel electrode PE3 may include a metal, an alloy, a metal nitride, a conductive metal oxide, a transparent conductive material, and/or the like. These materials may be used alone or in combination with each other. In one or more embodiments, each of the first pixel electrode PE1, the second pixel electrode PE2, and the third pixel electrode PE3 may have a stacked structure including ITO/Ag/ITO.

The pixel defining layer PDL may be located on the fourth insulating layer IL4. A solid (material) portion of the pixel defining layer PDL may cover a side portion of the first pixel electrode PE1. For example, a first pixel opening exposing a portion of an upper surface of the first pixel electrode PE1 to outside the pixel defining layer PDL may be defined in the pixel defining layer PDL. In addition, a material portion of the pixel defining layer PDL may cover a side portion of the second pixel electrode PE2. For example, a second pixel opening exposing a portion of an upper surface of the second pixel electrode PE2 to outside the pixel defining layer PDL may be defined in the pixel defining layer PDL. In addition, a material portion of the pixel defining layer PDL may cover a side portion of the third pixel electrode PE3. For example, a third pixel opening exposing a portion of an upper surface of the third pixel electrode PE3 to outside the pixel defining layer PDL may be defined in the pixel defining layer PDL. The various pixel openings may define an emission areas of a pixel area. An area between the pixel areas (or the emission areas) may be a non-emission area within the display area DA.

The pixel defining layer PDL may include an inorganic material or an organic material. In one or more embodiments, the pixel defining layer PDL may include an organic material such as epoxy resin, siloxane resin, and/or the like. These materials may be used alone or in combination with each other. In one or more embodiments, the pixel defining layer PDL may further include a light-blocking material containing a black pigment, a black dye, and/or the like.

The first light-emitting layer EML1 may be located on the first pixel electrode PE1. The first light-emitting layer EML1 may be located in the first pixel area PX1. For example, the first light-emitting layer EML1 may be located within the first pixel opening. The second light-emitting layer EML2 may be located on the second pixel electrode PE2. The second light-emitting layer EML2 may be located in the second pixel area PX2. For example, the second light-emitting layer EML2 may be located within the second pixel opening. The third light-emitting layer EML3 may be located on the third pixel electrode PE3. The third light-emitting layer EML3 may be located in the third pixel area PX3. For example, the third light-emitting layer EML3 may be located within the third pixel opening. Each of the first light-emitting layer EML1, the second light-emitting layer EML2, and the third light-emitting layer EML3 may include an organic material which emits light of a selected color.

The first common electrode CE1 may be located on the first light-emitting layer EML1. The first common electrode CE1 may be located in the first pixel area PX1. The first common electrode CE1 may be a cathode electrode of the first light-emitting element LED1. The second common electrode CE2 may be located on the second light-emitting layer EML2. The second common electrode CE2 may be located in the second pixel area PX2. The second common electrode CE2 may be a cathode electrode of the second light-emitting element LED2. The third common electrode CE3 may be located on the third light-emitting layer EML3. The third common electrode CE3 may be located in the third pixel area PX3. The third common electrode CE3 may be a cathode electrode of the third light-emitting element LED3.

Each of the first common electrode CE1, the second common electrode CE2, and the third common electrode CE3 may include a metal, an alloy, a metal nitride, a conductive metal oxide, a transparent conductive material, and/or the like. These materials may be used alone or in combination with each other. The various common electrodes may be portions of a common electrode layer. The common electrode layer may be continuous across the pixel areas and the non-emission area, without being limited thereto.

The encapsulation layer TFE may be located on the first common electrode CE1, the second common electrode CE2, and the third common electrode CE3. The encapsulation layer TFE may prevent impurities, moisture, and/or the like from penetrating into the first light-emitting element LED1, the second light-emitting element LED2, and the third light-emitting element LED3. The encapsulation layer TFE may include at least one inorganic layer and at least one organic layer. For example, the inorganic layer may include silicon oxide, silicon nitride, silicon oxynitride, and/or the like. These materials may be used alone or in combination with each other. The organic layer may include a polymer cured material such as polyacrylate. The encapsulation layer TFE and the light-emitting element layer together may be otherwise referred to a display element layer of the display device DD.

FIG. 3 is an enlarged cross-sectional view of an area A of FIG. 2. FIG. 4 is an enlarged cross-sectional view of an area X of FIG. 3. FIG. 5 is an enlarged cross-sectional view of an area B of FIG. 2.

Referring to FIG. 3, the first contact electrode SE1 may include a first portion SE1-A as a first thickness portion (or lower thickness portion), and a second portion SE1-B as a second thickness portion (or upper thickness portion).

The first portion SE1-A may be a portion which fills the first contact hole CNT1. For example, the first portion SE1-A may be a portion which contacts a first seed layer SL1, which will be described later. The first portion SE1-A may be a portion overlapping the second insulating layer IL2 in the first direction DR1, such as to be coplanar with the second insulating layer IL2.

The second portion SE1-B may be located on the first portion SE1-A. For example, the second portion SE1-B may be a portion which is not located in the first contact hole CNT1 and is entirely outside of the first contact hole CNT1. The second portion SE1-B may be a portion which does not overlap the second insulating layer IL2 in the first direction DR1. The second portion SE1-B may be coplanar with the third insulating layer IL3. The first portion SE1-A and the second portion SE1-B may be in direct contact with each other such as to form a single body or a continuous body. For example, the first portion SE1-A and the second portion SE1-B may together constitute the first contact electrode SE1. As used herein, elements which are in contact with each other may form an interface therebetween, like a physical interface.

In one or more embodiments, a width of the first contact hole CNT1 in the first direction DR1 may increase as a distance between the first contact hole CNT1 and the second portion SE1-B decreases. For example, the width of the first contact hole CNT1 in the first direction DR1 may increase along the third direction DR3. For example, a width W1 of an uppermost portion of the first contact hole CNT1 in the first direction DR1 may be greater than a width W2 of a lowermost portion of the first contact hole CNT1 in the first direction DR1. The width of the first contact hole CNT1 in the first direction DR1 may gradually increase from the width W2 to the width W1 along the third direction DR3. The width W1 of the uppermost portion of the first contact hole CNT1 in the first direction DR1 may be about 1 micrometer, but his disclosure is not necessarily limited thereto.

Since the first contact electrode SE1 does not penetrate the third insulating layer IL3, a recess may be considered defined in the third insulating layer IL3 into which the second thickness portion of the first contact electrode SE1 extends. The width W1 may be considered a maximum width of the first contact hole CNT1, a maximum width of the first contact electrode SE1 and/or a maximum width of the recess defined in the third insulating layer IL3. The width W1 may be defined at the upper surface of the second insulating layer IL2 and/or the lower surface of the third insulating layer IL3.

As described above, the width of the first contact hole CNT1 in the first direction DR1 may increase as a distance between the first contact hole CNT1 and the second portion SE1-B decreases. Accordingly, a width of the first portion SE1-A, which fills the first contact hole CNT1, in the first direction DR1 may also increase as a distance between the first portion SE1-A and the second portion SE1-B decreases. For example, the width of the first portion SE1-A in the first direction DR1 may increase as a distance between the first portion SE1-A and the first active pattern ACT1 increases. For example, the width of the first portion SE1-A in the first direction DR1 may increase along the third direction DR3.

In one or more embodiments, a width of the second portion SE1-B in the first direction DR1 may decrease as a distance between the second portion SE1-B and the first portion SE1-A increases. For example, the width of the second portion SE1-B in the first direction DR1 may decrease along the third direction DR3. For example, the width of the second portion SE1-B in the first direction DR1 may decrease as a distance between the second portion SE1-B and the first active pattern ACT1 increases. That is, a width of the first contact electrode SE1 both increases and decreases along the thickness direction.

In one or more embodiments, the second portion SE1-B may include a first surface S1 and a second surface S2 in a cross-sectional view, as outer surfaces of the first contact electrode SE1. The first surface S1 may be a side surface of the second portion SE1-B. The second surface S2 may be an upper surface of the second portion SE1-B, such as a surface which is furthest from the active layer. In one or more embodiments, a width W3 of the second surface S2 in the first direction DR1 may be smaller than the width of the first contact hole CNT1 in the first direction DR1. For example, the width W3 of the second surface S2 in the first direction DR1 may be smaller than the width W2 of the lowermost portion of the first contact hole CNT1 in the first direction DR1. The width W3 of the second surface S2 in the first direction DR1 may be about 0.6 micrometers, but this disclosure is not necessarily limited thereto.

In one or more embodiments, at least a portion of the first surface S1 may include a curved surface. For example, as illustrated in FIG. 3, the first surface S1 may entirely include a curved surface. However, this disclosure is not necessarily limited thereto, and a portion of the first surface S1 may be a curved surface while another portion of the first surface S1 may be a flat surface. In one or more embodiments, the first surface S1 may be a curved surface convex toward the first portion SE1-A. However, this disclosure is not necessarily limited thereto, and the first surface S1 may be a curved surface convex away from the first portion SE1-A.

In one or more embodiments, a thickness T1 as a depth of the first contact hole CNT1 in the third direction DR3 may be greater than a thickness T2 of the second portion SE1-B in the third direction DR3. For example, the thickness T1 of the first contact hole CNT1 in the third direction DR3 may be about 1 micrometer, and the thickness T2 of the second portion SE1-B in the third direction DR3 may be about 0.2 micrometers, this disclosure is not necessarily limited thereto.

In one or more embodiments, the display device (e.g., the display device DD of FIG. 2) may further include a plurality of seed layers. For example, as illustrated in FIG. 3, the display device may further include a first seed layer SL1 which fills the first contact hole CNT1, that is, covers an entirety of the surfaces defining the first contact hole CNT1. However, this disclosure is not necessarily limited thereto, and the first seed layer SL1 may also fill the second contact hole CNT2, the third contact hole CNT3, the fourth contact hole CNT4, the fifth contact hole CNT5, and the sixth contact hole CNT6 of FIG. 2. Here, surfaces defining the various contact holes may include a sidewall of the second insulating layer IL2 together with an upper surface of the active layer.

The first seed layer SL1 may be in direct contact with the first active pattern ACT1. In one or more embodiments, the first seed layer SL1 may cover a portion of the first contact electrode SE1. For example, as illustrated in FIG. 3, the first seed layer SL1 may cover a side surface and a lower surface of the first portion SE1-A. The first portion SE1-A may be connected (electrically) to the first active pattern ACT1 through the first seed layer SL1. As described above, the first contact electrode SE1 may be formed through an electroplating process such as to form an electroplated electrode. In this case, the electroplating process may be performed on the first seed layer SL1. In an embodiment, the material portions of first contact electrode SE1 together with the first seed layer SL1 may be considered as the first contact electrode SE1, without being limited thereto.

Referring further to FIG. 4, in one or more embodiments, the first seed layer SL1 may include a first layer SL1-A as a first thickness portion and a second layer SL1-B as a second thickness portion. The first layer SL1-A may be a portion in direct contact with the first active pattern ACT1. The second layer SL1-B may be located on the first layer SL1-A. The second layer SL1-B may be a portion in contact with the first portion SE1-A. In one or more embodiments, a thickness T3 of the first layer SL1-A in the third direction DR3 may be less than a thickness T4 of the second layer SL1-B in the third direction DR3. For example, the thickness T3 of the first layer SL1-A in the third direction DR3 may be equal to or greater than about 100 angstroms and equal to or less than about 200 angstroms, and the thickness T4 of the second layer SL1-B in the third direction DR3 may be equal to or greater than about 300 angstroms and equal to or less than about 3000 angstroms.

If the thickness T3 of the first layer SL1-A in the third direction DR3 is less than about 100 angstroms and the thickness T4 of the second layer SL1-B in the third direction DR3 is less than about 300 angstroms, the first seed layer SL1 may fail to sufficiently serve as a seed electrode for the electroplating process. If the thickness T3 of the first layer SL1-A in the third direction DR3 exceeds about 200 angstroms and the thickness T4 of the second layer SL1-B in the third direction DR3 exceeds about 3000 angstroms, seams, voids, and/or the like may be formed in the first layer SL1-A and the second layer SL1-B. In this case, when the first contact electrode SE1 is formed on the first seed layer SL1 through the electroplating process, problems such as non-uniform thickness of the first contact electrode SE1 may occur. While each of the thicknesses T3 of the first layer SL1-A and the thickness T4 of the second layer SL1-B have been described as a thickness in the third direction DR3, with regard to the portions of the first seed layer SL1 covering a side surface of the first portion SE1-A, each of the thicknesses T3 of the first layer SL1-A and the thickness T4 of the second layer SL1-B may be described as thickness in a direction perpendicular to the side surface of the first portion SE1-A. That is, thicknesses of the seed layer SL1 at various extended portions thereof may be define in a direction normal to a surface (or plane) along which such extended portions are provided.

In one or more embodiments, the first layer SL1-A and the second layer SL1-B may include different materials from each other. For example, the first layer SL1-A may include titanium (“Ti”), and the second layer SL1-B may include tantalum (“Ta”), but this disclosure is not necessarily limited thereto.

A structure of the first contact electrode SE1 has been described with reference to FIGS. 2 and 3, but this disclosure is not necessarily limited thereto, and each of the second contact electrode DE1, the third contact electrode SE2, the fourth contact electrode DE2, the fifth contact electrode SE3, the sixth contact electrode DE3, and the first contact electrode SE1 of FIG. 3 may have substantially a same structure.

For example, the second contact electrode DE1 may include a first (thickness) portion which fills the second contact hole CNT2 and a second (thickness) portion which is located on the first portion. The second portion of the second contact electrode DE1 may have a width in the first direction DR1 which decreases as a distance between the first portion of the second contact electrode DE1 and the second portion of the second contact electrode DE1 increases. In addition, the third contact electrode SE2 may include a first portion which fills the third contact hole CNT3 and a second portion which is located on the first portion. The second portion of the third contact electrode SE2 may have a width in the first direction DR1 which decreases as a distance between the first portion of the third contact electrode SE2 and the second portion of the third contact electrode SE2 increases. In addition, the fourth contact electrode DE2 may include a first portion which fills the fourth contact hole CNT4 and a second portion which is located on the first portion. The second portion of the fourth contact electrode DE2 may have a width in the first direction DR1 which decreases as a distance between the first portion of the fourth contact electrode DE2 and the second portion of the fourth contact electrode DE2 increases. In addition, the fifth contact electrode SE3 may include a first portion which fills the fifth contact hole CNT5 and a second portion which is located on the first portion. The second portion of the fifth contact electrode SE3 may have a width in the first direction DR1 which decreases as a distance between the first portion of the fifth contact electrode SE3 and the second portion of the fifth contact electrode SE3 increases. In addition, the sixth contact electrode DE3 may include a first portion which fills the sixth contact hole CNT6 and a second portion which is located on the first portion. The second portion of the sixth contact electrode DE3 may have a width in the first direction DR1 which decreases as a distance between the first portion of the sixth contact electrode DE3 and the second portion of the sixth contact electrode DE3 increases.

In addition, a structure of the first contact hole CNT1 has been described with reference to FIGS. 2 and 3, but this disclosure is not necessarily limited thereto, and the second contact hole CNT2, the third contact hole CNT3, the fourth contact hole CNT4, the fifth contact hole CNT5, the sixth contact hole CNT6, and the first contact hole CNT1 of FIG. 3 may have substantially a same structure.

Referring to FIG. 5, the first connection electrode CN1 may include a first portion CN1-A as a first thickness portion and a second portion CN1-B and a second thickness portion.

The first portion CN1-A may be a portion which fills the seventh contact hole CNT7. For example, the first portion CN1-A may be a portion which contacts a second seed layer SL2, which will be described later. The first portion CN1-A may be a portion overlapping the third insulating layer IL3 in the first direction DR1. That is, the first portion CN1-A may be coplanar with the third insulating layer IL3.

The second portion CN1-B may be located on the first portion CN1-A. For example, the second portion CN1-B may be a portion which is not located in the seventh contact hole CNT7, such as to be completely outside of the seventh contact hole CNT7. The second portion CN1-B may be a portion which does not overlap the third insulating layer IL3 in the first direction DR1, and instead is coplanar with the fourth insulating layer IL4. The first portion CN1-A and the second portion CN1-B may be in direct contact with each other, such as to form a single body or a continuous body. For example, the first portion CN1-A and the second portion CN1-B may together constitute the first connection electrode CN1. In an embodiment, the material portions of first connection electrode CN1 together with the second seed layer SL2 may be considered as the first connection electrode CN1, without being limited thereto

In one or more embodiments, a width of the seventh contact hole CNT7 in the first direction DR1 may increase as a distance between the seventh contact hole CNT7 and the second portion CN1-B decreases. For example, the width of the seventh contact hole CNT7 in the first direction DR1 may increase along the third direction DR3. For example, a width W4 of an uppermost portion of the seventh contact hole CNT7 in the first direction DR1 may be greater than a width W5 of a lowermost portion of the seventh contact hole CNT7 in the first direction DR1. The width of the seventh contact hole CNT7 in the first direction DR1 may gradually increase from the width W5 to the width W4 along the third direction DR3. The width W4 of the uppermost portion of the seventh contact hole CNT7 in the first direction DR1 may be about 1 micrometer, but this disclosure is not necessarily limited thereto.

As described above, the width of the seventh contact hole CNT7 in the first direction DR1 may increase as a distance between the seventh contact hole CNT7 and the second portion CN1-B decreases. Accordingly, a width of the first portion CN1-A which fills the seventh contact hole CNT7 in the first direction DR1 may also increase as a distance between the first portion CN1-A and the second portion CN1-B decreases. For example, the width of the first portion CN1-A in the first direction DR1 may increase as a distance between the first portion CN1-A and the second contact electrode DE1 increases. For example, the width of the first portion CN1-A in the first direction DR1 may increase along the third direction DR3.

In one or more embodiments, a width of the second portion CN1-B in the first direction DR1 may decrease as a distance between the second portion CN1-B and the first portion CN1-A increases. For example, the width of the second portion CN1-B in the first direction DR1 may decrease along the third direction DR3. For example, the width of the second portion CN1-B in the first direction DR1 may decrease as a distance between the second portion CN1-B and the first light-emitting element (e.g., the first light-emitting element LED1 of FIG. 2) decreases. For example, the width of the second portion CN1-B in the first direction DR1 may decrease as a distance between the second portion CN1-B and the first pixel electrode PE1 decreases.

In one or more embodiments, the second portion CN1-B may include a first surface S3 and a second surface S4 in a cross-sectional view. The first surface S3 may be a side surface of the second portion CN1-B. The second surface S4 may be an upper surface of the second portion CN1-B. In one or more embodiments, a width W6 of the second surface S4 in the first direction DR1 may be smaller than the width of the seventh contact hole CNT7 in the first direction DR1. For example, the width W6 of the second surface S4 in the first direction DR1 may be smaller than the width W5 of the lowermost portion of the seventh contact hole CNT7 in the first direction DR1. The width W6 of the second surface S4 in the first direction DR1 may be about 0.6 micrometers, but this disclosure is not necessarily limited thereto.

Since the first connection electrode CN1 does not penetrate the fourth insulating layer IL4, a recess may be considered defined in the fourth insulating layer IL4 into which the second thickness portion of the first connection electrode CN1 extends. Such recess may be open in a direction towards the active layer. The width W4 may be considered a maximum width of the seventh contact hole CNT7, a maximum width of the first connection electrode CN1 and/or a maximum width of the recess defined in the fourth insulating layer IL4. The width W4 may be defined at the upper surface of the third insulating layer IL3 and/or the lower surface of the fourth insulating layer IL4.

In one or more embodiments, at least a portion of the first surface S3 may include a curved surface. For example, as illustrated in FIG. 5, the first surface S3 may entirely include a curved surface. However, this disclosure is not necessarily limited thereto, and a portion of the first surface S3 may be a curved surface while another portion of the first surface S3 may be a flat surface. In one or more embodiments, the first surface S3 may be a curved surface convex toward the first portion CN1-A. However, this disclosure is not necessarily limited thereto, and the first surface S3 may be a curved surface convex away from the first portion CN1-A.

In one or more embodiments, a thickness T5 as a depth of the seventh contact hole CNT7 in the third direction DR3 may be greater than a thickness T6 of the second portion CN1-B in the third direction DR3. For example, the thickness T5 of the seventh contact hole CNT7 in the third direction DR3 may be about 1 micrometer, and the thickness T6 of the second portion CN1-B in the third direction DR3 may be about 0.2 micrometers, but this disclosure is not necessarily limited thereto.

In one or more embodiments, the display device (e.g., the display device DD of FIG. 2) may further include a plurality of seed layers. For example, as illustrated in FIG. 5, the display device may further include a second seed layer SL2 which fills (or lines) the seventh contact hole CNT7. However, this disclosure is not necessarily limited thereto, and the second seed layer SL2 may also fill the eighth contact hole CNT8 and the ninth contact hole CNT9 of FIG. 2.

The second seed layer SL2 may be in direct contact with the second contact electrode DE1. In one or more embodiments, the second seed layer SL2 may cover a portion of the first connection electrode CN1. For example, as illustrated in FIG. 5, the second seed layer SL2 may cover a side surface of the first portion CN1-A and a lower surface of the first portion CN1-A. The first portion CN1-A may be connected to the second contact electrode DE1 through the second seed layer SL2. As described above, the first connection electrode CN1 may be formed through an electroplating process. In this case, the electroplating process may be performed on the second seed layer SL2.

In one or more embodiments, the second seed layer SL2 of FIG. 5 and the first seed layer SL1 of FIG. 4 may have substantially a same structure. In addition, the second seed layer SL2 of FIG. 5 and the first seed layer SL1 of FIG. 4 may include substantially a same material as each other.

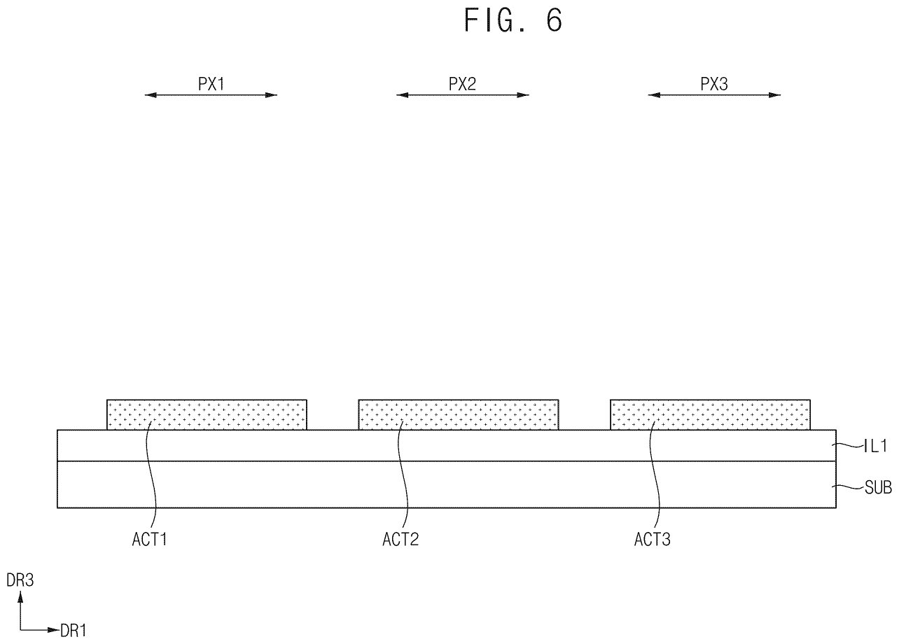

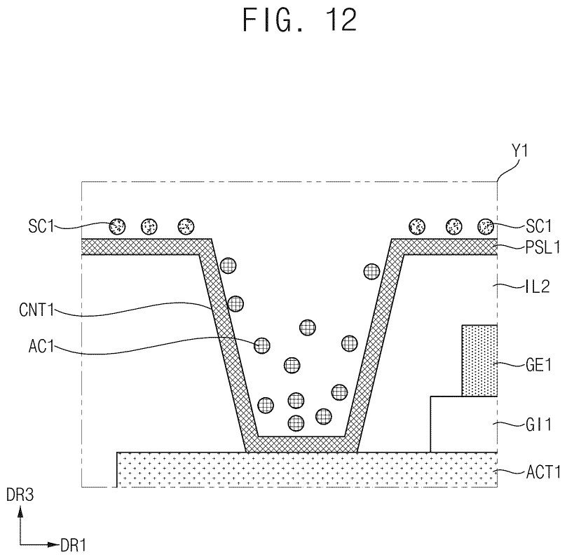

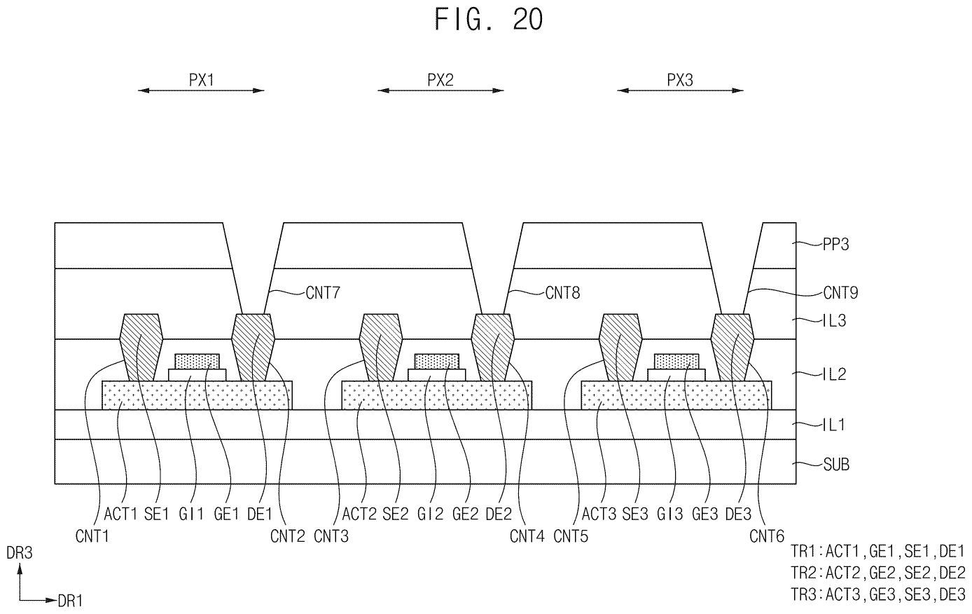

FIGS. 6, 7, 8, 9, 10, 11, 12, 13, 14, 15, 16, 17, 18, 19, 20, 21, 22, 23, 24, 25, 26, 27, 28, and 29 are cross-sectional views illustrating a method of manufacturing (or providing) the display device DD of FIG. 2. Specifically, FIG. 12 is a cross-sectional view illustrating an enlarged view of an area Y1 of FIG. 11, and FIG. 22 is a cross-sectional view illustrating an enlarged view of an area Y2 area of FIG. 20.

Referring to FIG. 6, the first insulating layer IL1 may be formed on the substrate SUB. The substrate SUB may include a transparent material or an opaque material. The substrate SUB may be formed of (or include) a transparent resin substrate. Example of the transparent resin substrate may include a polyimide substrate. In this case, the polyimide substrate may include a first organic layer, a first barrier layer, a second organic layer, and/or the like. In another embodiment, the substrate SUB may include a quartz substrate (e.g. a synthetic quartz substrate, a fluorine-doped quartz substrate), a calcium fluoride substrate, a soda lime glass substrate, a non-alkali glass substrate, and/or the like. These materials may be used alone or in combination with each other.

The first insulating layer IL1 may include inorganic materials such as silicon oxide (“SiOₓ”), silicon nitride (“SiNₓ”), silicon carbide (“SiCₓ”), silicon oxynitride (“SiOₓN_{y}”), silicon oxycarbide (“SiOₓC_{y}”), and/or the like. These materials may be used alone or in combination with each other.

The first active pattern ACT1, the second active pattern ACT2, and the third active pattern ACT3 within an active layer may be formed on the first insulating layer IL1 as respective patterns of the active layer. The first active pattern ACT1 may be formed in a portion of the first pixel area PX1, the second active pattern ACT2 may be formed in a portion of the second pixel area PX2, and the third active pattern ACT3 may be formed in a portion of the third pixel area PX3, but this disclosure is not necessarily limited thereto. Each of the first active pattern ACT1, the second active pattern ACT2, and the third active pattern ACT3 may include an inorganic semiconductor (e.g., amorphous silicon semiconductor, polysilicon semiconductor, a metal oxide semiconductor,), an organic semiconductor, and/or the like. These materials may be used alone or in combination with each other. The metal oxide semiconductor may include a binary compound (“ABₓ”), a ternary compound (“ABₓC_{y}”), a quaternary compound (“ABₓC_{y}D_{z}”), and/or the like including indium (“In”), zinc (“Zn”), gallium (“Ga”), tin (“Sn”), titanium (“Ti”), aluminum (“Al”), hafnium (“Hf”), zirconium (“Zr”), magnesium (“Mg”), and/or the like. These materials may be used alone or in combination with each other. For example, the metal oxide semiconductor may include zinc oxide (“ZnOₓ”), gallium oxide (“GaOₓ”), tin oxide (“SnOₓ”), indium oxide (“InOₓ”), indium gallium oxide (“IGO”), indium zinc oxide (“IZO”), indium tin oxide (“ITO”), indium zinc tin oxide (“IZTO”), and indium gallium zinc oxide (“IGZO”). These materials may be used alone or in combination with each other.

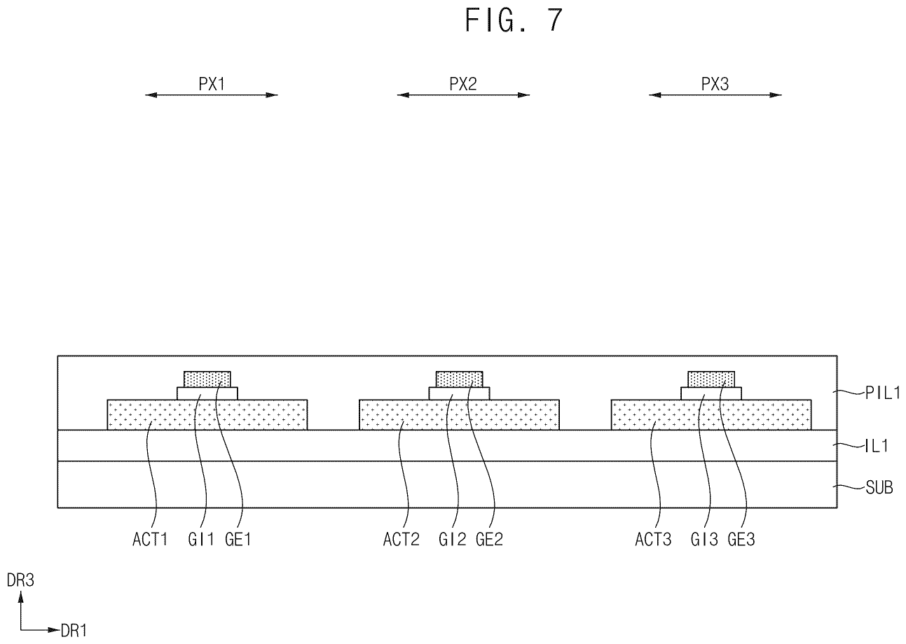

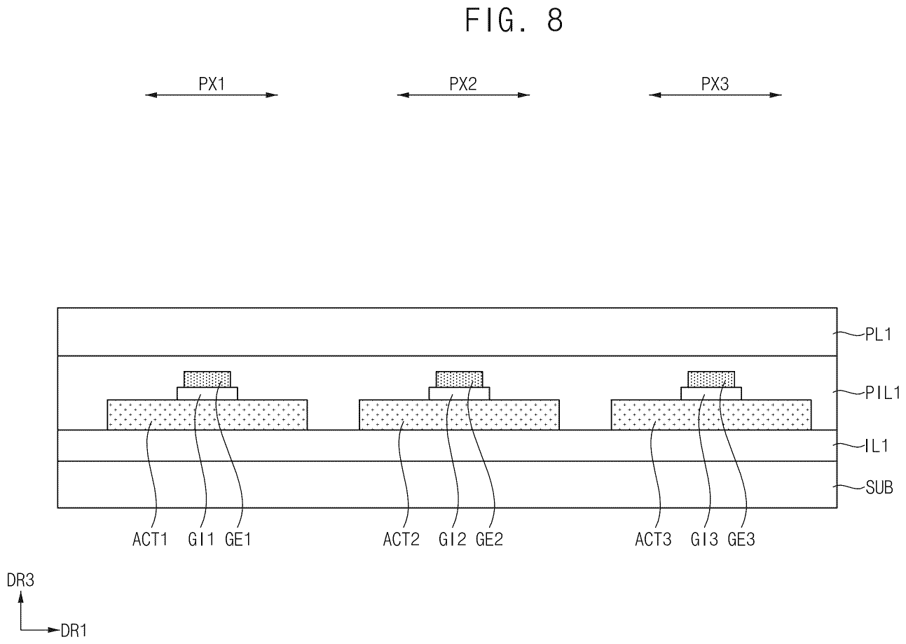

Referring to FIG. 7, the first gate insulating layer GI1 may be formed on the first active pattern ACT1. The second gate insulating layer GI2 may be formed on the second active pattern ACT2. The third gate insulating layer GI3 may be formed on the third active pattern ACT3. Each of the first gate insulating layer GI1, the second gate insulating layer GI2, and the third gate insulating layer GI3 as respective patterns of a gate insulating layer may include inorganic materials such as silicon oxide (“SiOₓ”), silicon nitride (“SiNₓ”), silicon carbide (“SiCₓ”), silicon oxynitride (“SiOₓN_{y}”), silicon oxycarbide (“SiOₓC_{y}”), and/or the like. These materials may be used alone or in combination with each other.

The first gate electrode GE1 may be formed on the first gate insulating layer GI1. The second gate electrode GE2 may be formed on the second gate insulating layer GI2. The third gate electrode GE3 may be formed on the third gate insulating layer GI3. Each of the first gate electrode GE1, the second gate electrode GE2, and the third gate electrode GE3 of a gate electrode layer may include a metal, an alloy, a metal nitride, a conductive metal oxide, a transparent conductive material, and/or the like. Examples of the metal may include silver (“Ag”), molybdenum (“Mo”), aluminum (“Al”), tungsten (“W”), copper (“Cu”), nickel (“Ni”), chromium (“Cr”), titanium (“Ti”), tantalum (“Ta”), platinum (“Pt”), scandium (“Sc”), and/or the like. These materials may be used alone or in combination with each other. Examples of the conductive metal oxide may include indium tin oxide, indium zinc oxide, and/or the like. These materials may be used alone or in combination with each other. In addition, examples of the metal nitride may include aluminum nitride (“AlNₓ”), tungsten nitride (“WNₓ”), chromium nitride (“CrNₓ”), and/or the like. These materials may be used alone or in combination with each other.

A first preliminary insulating layer PIL1 may be formed on the first insulating layer IL1. The first preliminary insulating layer PIL1 may be formed to cover the first active pattern ACT1, the second active pattern ACT2, and the third active pattern ACT3. In addition, the first preliminary insulating layer PIL1 may be formed to cover the first gate insulating layer GI1, the second gate insulating layer GI2, and the third gate insulating layer GI3. In addition, the first preliminary insulating layer PIL1 may be formed to cover the first gate electrode GE1, the second gate electrode GE2, and the third gate electrode GE3. The first preliminary insulating layer PIL1 may include inorganic materials such as silicon oxide (“SiOₓ”), silicon nitride (“SiNₓ”), silicon carbide (“SiCₓ”), silicon oxynitride (“SiOₓN_{y}”), silicon oxycarbide (“SiOₓC_{y}”), and/or the like. These materials may be used alone or in combination with each other.

Referring to FIG. 8, a first photoresist layer PL1 may be formed on the first preliminary insulating layer PIL1. A mask may be placed on the first photoresist layer PL1. The mask may include a light-transmitting area and a blocking area according to various locations along the substrate SUB.

The light-transmitting area may be an area (e.g., a planar area) of the mask through which light passes and reaches the first photoresist layer PL1. The blocking area may be an area of the mask through which light does not pass and therefore does not reach the first photoresist layer PL1. The first photoresist layer PL1 may be a positive photoresist layer or a negative photoresist layer. For convenience of explanation, a case in which the first photoresist layer PL1 is a negative photoresist layer will be described as an example.

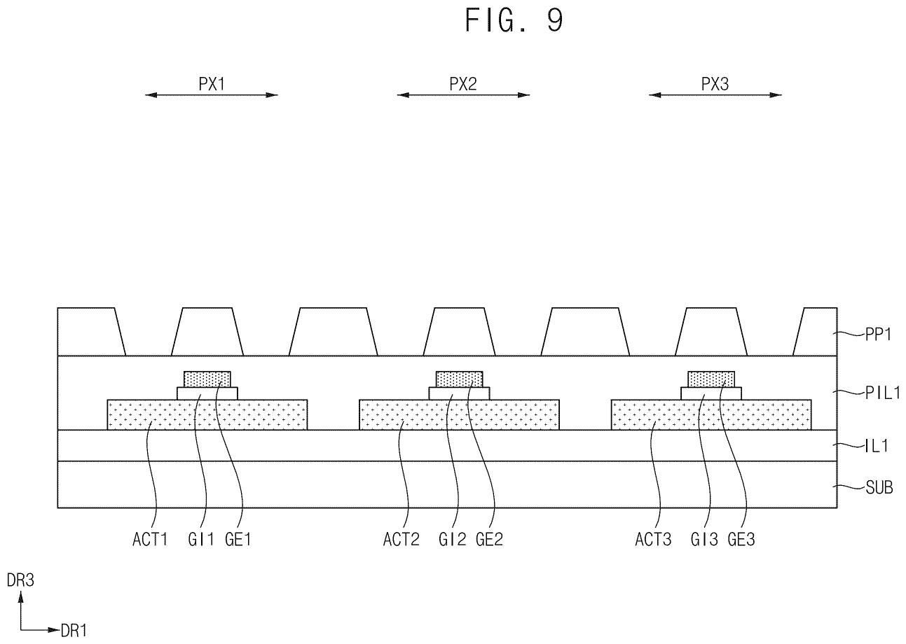

Referring to FIGS. 8 and 9, the first photoresist layer PL1 may be subjected to an exposure process and then a development process. Accordingly, a first photoresist pattern PP1 may be formed. For example, a portion of the first photoresist layer PL1 overlapping the blocking area of the mask in the plan view may be removed.

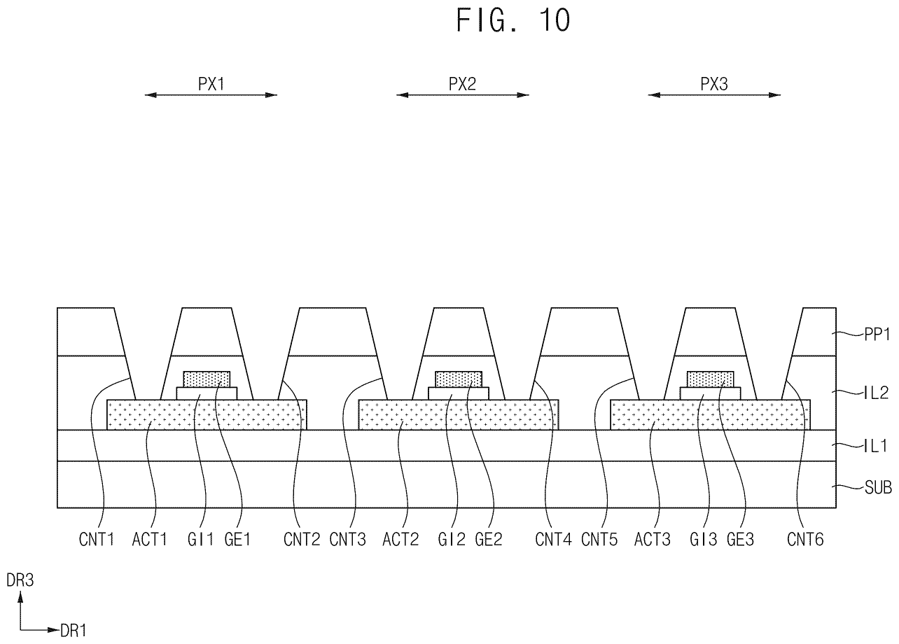

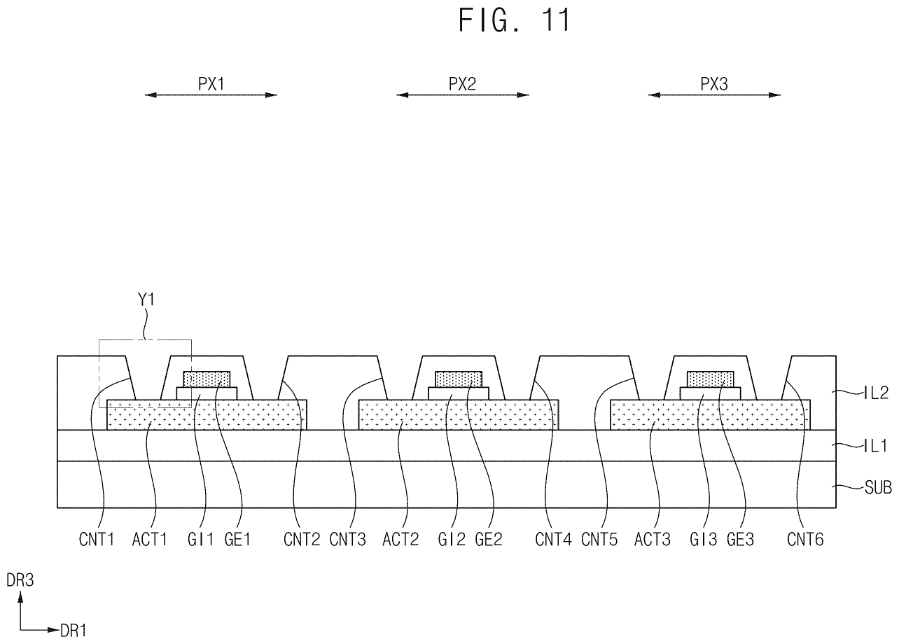

Referring to FIGS. 9 and 10, a portion of the first preliminary insulating layer PIL1 may be removed through an etching process using the first photoresist pattern PP1. For example, a portion of the first preliminary insulating layer PIL1 may be removed through a dry etching process using the first photoresist pattern PP1. Accordingly, the second insulating layer IL2 including the first contact hole CNT1, the second contact hole CNT2, the third contact hole CNT3, the fourth contact hole CNT4, the fifth contact hole CNT5, and the sixth contact hole CNT6 as lower contact holes may be formed. Here, an upper surface of the active layer may be exposed to outside the second insulating layer IL2 at the lower contact holes overlapping the (electrical) contact areas of the active layer.

Referring to FIGS. 10 and 11, the first photoresist pattern PP1 may be removed. For example, the first photoresist pattern PP1 may be removed through a strip process, but this disclosure is not necessarily limited thereto. Here, upper surfaces and side surfaces of the second insulating layer IL2 which define the various lower contact holes, together with the upper surface of the active layer are exposed (e.g., exposed surfaces). The side surfaces of the second insulating layer IL2 together with a corresponding upper surface of the active layer may define the profile, depth, etc. of the lower contact holes.

Referring to FIGS. 11 and 12, a first preliminary seed layer PSL1 may be formed on the second insulating layer IL2. The first preliminary seed layer PSL1 may be formed to extend from the upper exposed surface of the second insulating layer IL2 and fill (or line) the first contact hole CNT1, the second contact hole CNT2, the third contact hole CNT3, the fourth contact hole CNT4, the fifth contact hole CNT5, and the sixth contact hole CNT6. For example, FIG. 12 may illustrate a structure in which the first preliminary seed layer PSL1 is formed to fill the first contact hole CNT1, but this disclosure is not necessarily limited thereto, and the first preliminary seed layer PSL1 may also be formed to fill the second contact hole CNT2, the third contact hole CNT3, the fourth contact hole CNT4, the fifth contact hole CNT5, and the sixth contact hole CNT6. For example, the first preliminary seed layer PSL1 may be continuously formed across the first pixel area PX1, the second pixel area PX2, and the third pixel area PX3, in areas corresponding to both the emission and non-emission areas. The first preliminary seed layer PSL1 may include a first layer (e.g., first thickness portion) and a second layer (e.g., second thickness portion) which is located on the first layer. The first layer may include titanium (“Ti”), and the second layer may include tantalum (“Ta”), but this disclosure is not necessarily limited thereto.

Referring further to FIG. 13, a first electrode layer SDL1 may be formed on the second insulating layer IL2 and in the lower contact holes which have the first preliminary seed layer PSL1 therein. The first electrode layer SDL1 may be formed to fill volumes of the first contact hole CNT1, the second contact hole CNT2, the third contact hole CNT3, the fourth contact hole CNT4, the fifth contact hole CNT5, and the sixth contact hole CNT6 which are not occupied by the first preliminary seed layer PSL1. While not explicitly shown in FIG. 13, it will be understood that the first preliminary seed layer PSL1 is between the first electrode layer SDL1 and the underlying stacked structure defining the lower contact holes.

In one or more embodiments, the first electrode layer SDL1 may be formed by performing an electroplating process on the first preliminary seed layer PSL1. In one or more embodiments, the electroplating process may be performed using a copper plating solution. The copper plating solution may include an aqueous electrolyte solution, a first accelerator AC1 and a first suppressor SC1. The aqueous electrolyte solution may include a water-soluble copper salt, the first accelerator AC1 may promote a reduction reaction of copper, and the first suppressor SC1 may suppress the reduction reaction of copper.

After the substrate SUB is provided in the aqueous electrolyte solution, power may be applied to a target (pure copper) serving as an (electroplating) anode and the substrate SUB serving as a (electroplating) cathode. Thereafter, copper ions released from the target may move through the aqueous electrolyte solution onto the substrate SUB, and the first electrode layer SDL1 may be formed on the first preliminary seed layer PSL1.

In one or more embodiments, in the electroplating process, the first accelerator AC1 may be located in an area which overlaps the first contact hole CNT1, the second contact hole CNT2, the third contact hole CNT3, the fourth contact hole CNT4, the fifth contact hole CNT5, and the sixth contact hole CNT6 in the plan view, and the first suppressor SC1 may be located in an area spaced apart from the first contact hole CNT1, the second contact hole CNT2, the third contact hole CNT3, the fourth contact hole CNT4, the fifth contact hole CNT5, and the sixth contact hole CNT6 in the plan view. For example, the first accelerator AC1 may be located in the first contact hole CNT1, the second contact hole CNT2, the third contact hole CNT3, the fourth contact hole CNT4, the fifth contact hole CNT5, and the sixth contact hole CNT6, and the first suppressor SC1 may be located on the second insulating layer IL2. Accordingly, a formation rate of the first electrode layer SDL1 in the first contact hole CNT1, the second contact hole CNT2, the third contact hole CNT3, the fourth contact hole CNT4, the fifth contact hole CNT5, and the sixth contact hole CNT6 may be faster than a formation rate of the first electrode layer SDL1 on the second insulating layer IL2. For example, a thickness of the first electrode layer SDL1 in the first contact hole CNT1, the second contact hole CNT2, the third contact hole CNT3, the fourth contact hole CNT4, the fifth contact hole CNT5, and the sixth contact hole CNT6 may be greater than a thickness of the first electrode layer SDL1 outside of the lower contact holes and on the second insulating layer IL2.

A molecular weight of the first accelerator AC1 may be smaller than a molecular weight of the first suppressor SC1. For example, the first accelerator AC1 may include bis-(3-sulfopropyl) disulfide (“SPS”), mercaptopropanesulfonic acid (“MPS”), 3-N, N-dimethylaminodithiocarbamoyl-1-propanesulfonic acid (“DPS”), and/or the like. These materials may be used alone or in combination with each other. In addition, the first suppressor SC1 may include polyethylene oxide (“PEO”), polypropylene oxide (“PPO”), polyethylene glycol (“PEG”), polypropylene glycol (“PPG”), and/or the like. These materials may be used alone or in combination with each other. Although not illustrated in FIG. 12, a leveler including polyethyleneimine (“PEI”), hydroxyethyl cellulose (“HEC”), and/or the like may be further located on the second insulating layer IL2.

As the first electrode layer SDL1 is formed through the electroplating process, the first electrode layer SDL1 may include a material included in the first accelerator AC1 and a material included in the first suppressor SC1. For example, the first electrode layer SDL1 may include bis-(3-sulfopropyl) disulfide (“SPS”), mercaptopropanesulfonic acid (“MPS”), 3-N, N-dimethylaminodithiocarbamoyl-1-propanesulfonic acid (“DPS”), polyethylene oxide (“PEO”), polypropylene oxide (“PPO”), polyethylene glycol (“PEG”), polypropylene glycol (“PPG”), and/or the like. These materials may be used alone or in combination with each other.

In an embodiment, a display device DD includes a first insulating layer (like IL2) in which a first contact hole (like CNT1 through CNT6) is defined, a second insulating layer (like IL3) on the first insulating layer, a light-emitting element on the second insulating layer; and a contact electrode (like SE or DE) electrically connected to the light-emitting element. The contact electrode includes a first (lower) portion in the first contact hole of the first insulating layer, the first portion extended out of the first contact hole and into the second insulating layer to define a second (upper) portion of the contact electrode and a width of the second portion decreasing in a direction from the first insulating layer to the second insulating layer.

A side surface of the contact electrode at the second portion may include a curved surface. The contact electrode may further include an upper surface at the second portion, and a width of the upper surface of the contact electrode smaller than a maximum width of the first contact hole.

The contact electrode may further include an electroplating layer (like SDL1) which defines the first portion and the second portion, and the electroplating layer may include at least one selected from bis-(3-sulfopropyl) disulfide, mercaptopropanesulfonic acid, and 3-N, N-dimethylaminodithiocarbamoyl-1-propanesulfonic acid.

The display device DD may further include a transistor connected to the light-emitting element, where the transistor includes the contact electrode having the first portion and the second portion. The transistor may include an active pattern and the contact electrode which is connected to the active pattern at the first portion of the contact electrode.

The display device DD may further include the first contact hole provided in plural in the first insulating layer, the contact electrode provided in plural, and among the contact electrodes, the transistor including a first contact electrode and a second contact electrode in first contact holes of the insulating layer, respectively. A second contact hole may be defined in the second insulating layer, the second contact hole exposing the second portion of the second contact electrode to outside the second insulating layer. The display device DD may further include a connection contact electrode (like CN) among the contact electrodes which is in the second contact hole and connects the second contact electrode of the transistor to the light-emitting element.

The display device DD may further include an electroplating seed layer (like SL1) in the first contact hole, where the electroplating seed layer is between the first insulating layer and the first portion of the contact electrode. The electroplating seed layer may include in order from the first insulating layer to the first portion of the contact electrode, a first layer having a thickness equal to or greater than about 100 angstroms and equal to or less than about 200 angstroms; and a second layer on the first layer and having a thickness equal to or greater than about 300 angstroms and equal to or less than about 3000 angstroms.

A method of forming the first electrode layer SDL1 has been described with reference to FIGS. 8, 9, 10, 11, 12, and 13. The first electrode layer SDL1 may be formed through a damascene process. For example, the first electrode layer SDL1 may be formed by performing the electroplating process after forming the second insulating layer IL2 including the first contact hole CNT1, the second contact hole CNT2, the third contact hole CNT3, the fourth contact hole CNT4, the fifth contact hole CNT5, and the sixth contact hole CNT6 which are defined therein. That is, the first electrode layer SDL1 may be considered an electroplate layer on the seed layer.

Referring to FIG. 14, a second photoresist layer PL2 may be formed on the first electrode layer SDL1. A mask may be placed on the second photoresist layer PL2. The mask may include a light-transmitting area and a blocking area.

The light-transmitting area may be an area of the mask through which light passes and reaches the second photoresist layer PL2. The blocking area may be an area of the mask through which light does not pass and therefore does not reach the second photoresist layer PL2. The second photoresist layer PL2 may be a positive photoresist layer or a negative photoresist layer. For convenience of explanation, a case in which the second photoresist layer PL2 is a negative photoresist layer will be described as an example.

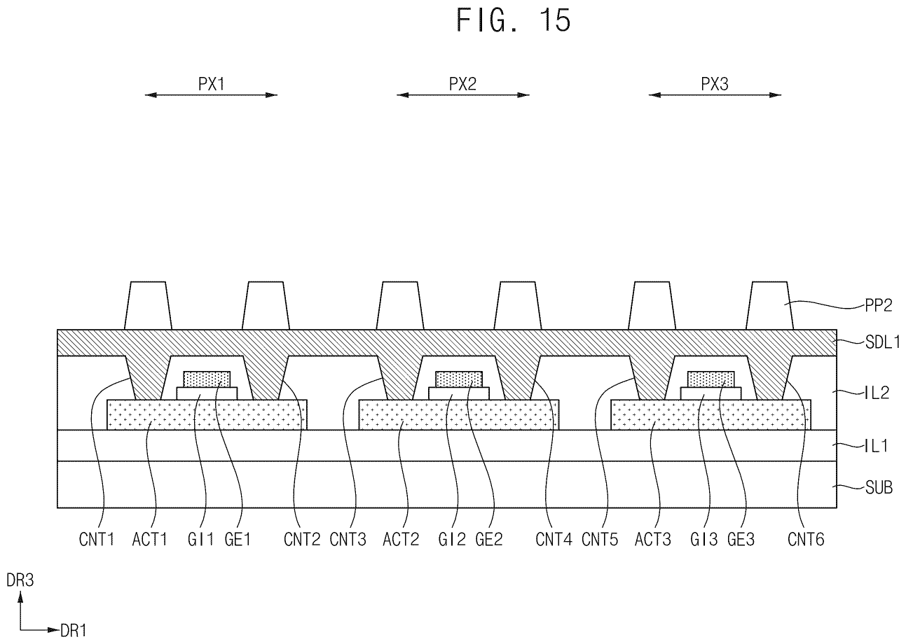

Referring to FIGS. 14 and 15, the second photoresist layer PL2 may be subjected to an exposure process and then a development process. Accordingly, a second photoresist pattern PP2 may be formed. For example, a portion of the second photoresist layer PL2 overlapping with the blocking area of the mask in the plan view may be removed.

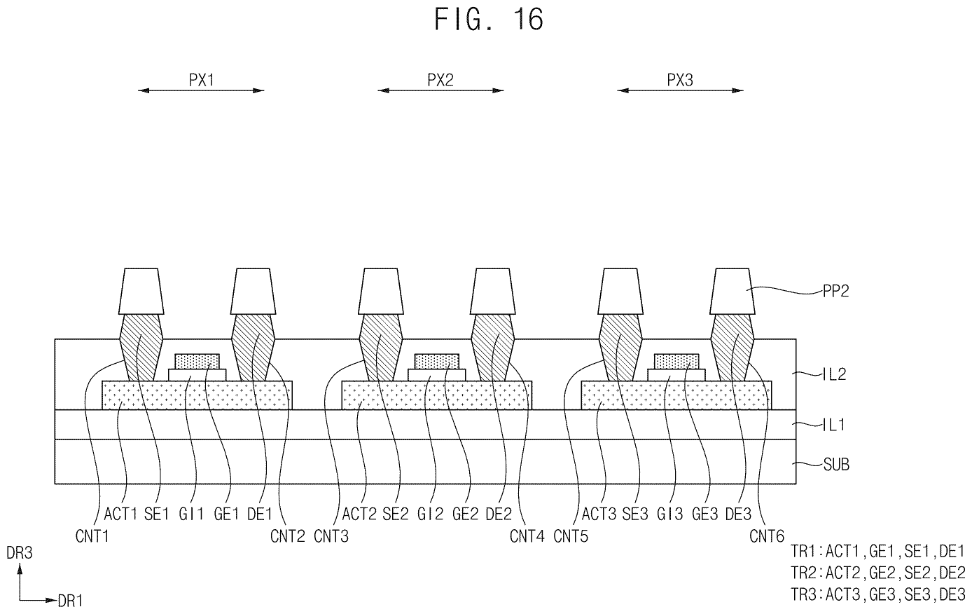

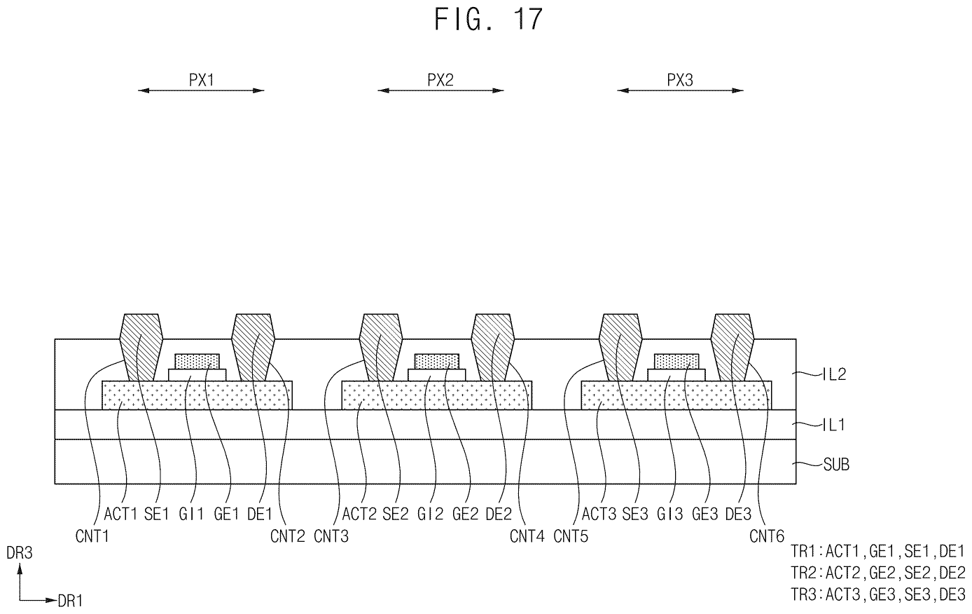

Referring to FIGS. 15 and 16, a portion of the first electrode layer SDL1 may be removed through an etching process using the second photoresist pattern PP2. For example, the portion of the first electrode layer SDL1 may be removed through a wet etching process using the second photoresist pattern PP2. For example, a portion of the first electrode layer SDL1 which is spaced apart from the second photoresist pattern PP2 in the plan view may be removed. For example, a portion of the first electrode layer SDL1 located on the second insulating layer IL2 and non-overlapping the lower contact holes may be removed through the wet etching process. The wet etching process may be an isotropic etching process. Accordingly, even a portion of the first electrode layer SDL1 located under the second photoresist pattern PP2 may also be removed. For example, as illustrated in FIG. 16, a first undercut area in which the second photoresist pattern PP2 extends further than a side surface of the first contact electrode SE1 such that the lower surface and the first contact electrode SE1 are spaced apart from each other without contact may be formed on the second insulating layer IL2.

In addition, a second undercut area in which the second photoresist pattern PP2 and the second contact electrode DE1 are spaced apart from each other without contact may be formed on the second insulating layer IL2. In addition, a third undercut area in which the second photoresist pattern PP2 and the third contact electrode SE2 are spaced apart from each other without contact may be formed on the second insulating layer IL2. In addition, a fourth undercut area in which the second photoresist pattern PP2 and the fourth contact electrode DE2 are spaced apart from each other without contact may be formed on the second insulating layer IL2. In addition, a fifth undercut area in which the second photoresist pattern PP2 and the fifth contact electrode SE3 are spaced apart from each other without contact may be formed on the second insulating layer IL2. In addition, a sixth undercut area in which the second photoresist pattern PP2 and the sixth contact electrode DE3 are spaced apart from each other without contact may be formed on the second insulating layer IL2.

Here, the various transistor electrodes (e.g., contact electrodes) may protrude outside of the lower contact holes to define extended portions of the transistor electrodes on which the second photoresist pattern PP2 remains.

In one or more embodiments, at least a portion of the first preliminary seed layer (e.g., the first preliminary seed layer PSL1 of FIG. 12) may be removed through the wet etching process. For example, a portion of the first preliminary seed layer which is spaced apart from or non-overlapping the first contact hole CNT1, the second contact hole CNT2, the third contact hole CNT3, the fourth contact hole CNT4, the fifth contact hole CNT5, and the sixth contact hole CNT6 in the plan view may be removed through the wet etching process. Accordingly, the first seed layer (e.g., the first seed layer SL1 of FIG. 3) may be formed. Although not explicitly shown in FIG. 16, the first seed layer SL1 may remain in the various lower contact holes, to be between a respective contact electrode and the surfaces which form a corresponding lower contact hole.

For example, the portion of the first electrode layer SDL1 which is spaced apart from the second photoresist pattern PP2 in the plan view and the portion of the first electrode layer SDL1 located under the protruding portion of the second photoresist pattern PP2 may be removed. As a result, the first contact electrode SE1, the second contact electrode DE1, the third contact electrode SE2, the fourth contact electrode DE2, the fifth contact electrode SE3, and the sixth contact electrode DE3 as the transistor electrodes may be formed.

Referring to FIGS. 16 and 17, the second photoresist pattern PP2 may be removed. For example, the second photoresist pattern PP2 may be removed through a stripping process, but this disclosure is not necessarily limited thereto.

Referring to FIGS. 13 and 16, as described above, the first electrode layer SDL1 may be formed to fill remaining volumes the first contact hole CNT1, the second contact hole CNT2, the third contact hole CNT3, the fourth contact hole CNT4, the fifth contact hole CNT5, and the sixth contact hole CNT6 which are not occupied by the first seed layer SL1, through the damascene process. For example, the first electrode layer SDL1 may be formed by performing the electroplating process on the seed layer, after forming the second insulating layer IL2 including the first contact hole CNT1, the second contact hole CNT2, the third contact hole CNT3, the fourth contact hole CNT4, the fifth contact hole CNT5, and the sixth contact hole CNT6 defined in the second insulating layer IL2. Each of the first portion (e.g., the first portion SE1-A of FIG. 3) of the first contact electrode SE1 which fills the first contact hole CNT1, the first portion of the second contact electrode DE1 which fills the second contact hole CNT2, the first portion of the third contact electrode SE2 which fills the third contact hole CNT3, the first portion of the fourth contact electrode DE2 which fills the fourth contact hole CNT4, the first portion of the fifth contact electrode SE3 which fills the fifth contact hole CNT5, and the first portion of the sixth contact electrode DE3 which fills the sixth contact hole CNT6 may be understood as being formed through the damascene process (or the electroplating process).

As resolution of the display device (e.g., the display device DD of FIG. 1) increases, aspect ratio of each of the first contact hole CNT1, the second contact hole CNT2, the third contact hole CNT3, the fourth contact hole CNT4, the fifth contact hole CNT5, and the sixth contact hole CNT6 may increase. According to one or more embodiments, as the first portion of the first contact electrode SE1 which fills the first contact hole CNT1, the first portion of the second contact electrode DE1 which fills the second contact hole CNT2, the first portion of the third contact electrode SE2 which fills the third contact hole CNT3, the first portion of the fourth contact electrode DE2 which fills the fourth contact hole CNT4, the first portion of the fifth contact electrode SE3 which fills the fifth contact hole CNT5, and the first portion of the sixth contact electrode DE3 which fills the sixth contact hole CNT6 are formed through the damascene process (or the electroplating process), even if the aspect ratio of each of the first contact hole CNT1, the second contact hole CNT2, the third contact hole CNT3, the fourth contact hole CNT4, the fifth contact hole CNT5, and the sixth contact hole CNT6 increases, the first portion of the first contact electrode SE1, the first portion of the second contact electrode DE1, the first portion of the third contact electrode SE2, the first portion of the fourth contact electrode DE2, the first portion of the fifth contact electrode SE3, and the first portion of the sixth contact electrode DE3 may not include skew, seam, void, and/or the like. Accordingly, the first contact electrode SE1, the second contact electrode DE1, the third contact electrode SE2, the fourth contact electrode DE2, the fifth contact electrode SE3, and the sixth contact electrode DE3 suitable for a high-resolution display device may be formed.

In addition, a portion of the first electrode layer SDL1 located above the second insulating layer IL2 may be removed through the wet etching process. Each of the second portion (e.g., the second portion SE1-B of FIG. 3) of the first contact electrode SE1, the second portion of the second contact electrode DE1, the second portion of the third contact electrode SE2, the second portion of the fourth contact electrode DE2, the second portion of the fifth contact electrode SE3, and the second portion of the sixth contact electrode DE3 may be understood as being formed through the damascene process (or the electroplating process) and the wet etching process. Accordingly, each of the first contact electrode SE1, the second contact electrode DE1, the third contact electrode SE2, the fourth contact electrode DE2, the fifth contact electrode SE3, and the sixth contact electrode DE3 may be formed without a chemical mechanical polishing process. Accordingly, each of the first contact electrode SE1, the second contact electrode DE1, the third contact electrode SE2, the fourth contact electrode DE2, the fifth contact electrode SE3, and the sixth contact electrode DE3 may be formed through the damascene process (or the electroplating process) and the wet etching process without requiring equipment for performing the chemical mechanical polishing process. Accordingly, manufacturing cost and manufacturing time of the display device may be reduced.

In summary, the first contact electrode SE1, the second contact electrode DE1, the third contact electrode SE2, the fourth contact electrode DE2, the fifth contact electrode SE3, and the sixth contact electrode DE3, which are suitable for a high-resolution display device, may be formed through the damascene process (or the electroplating process) and the wet etching process with reduced manufacturing cost and manufacturing time.

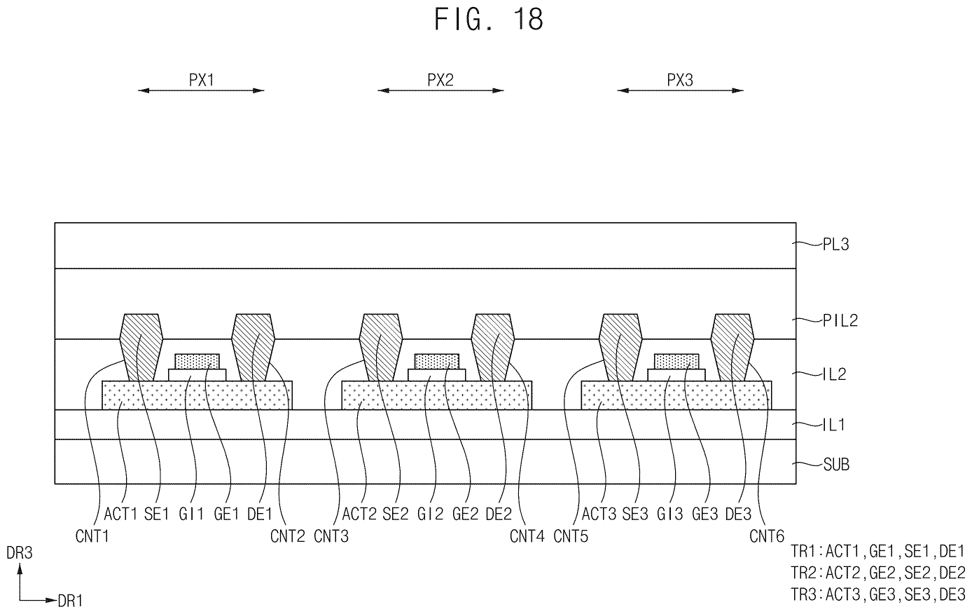

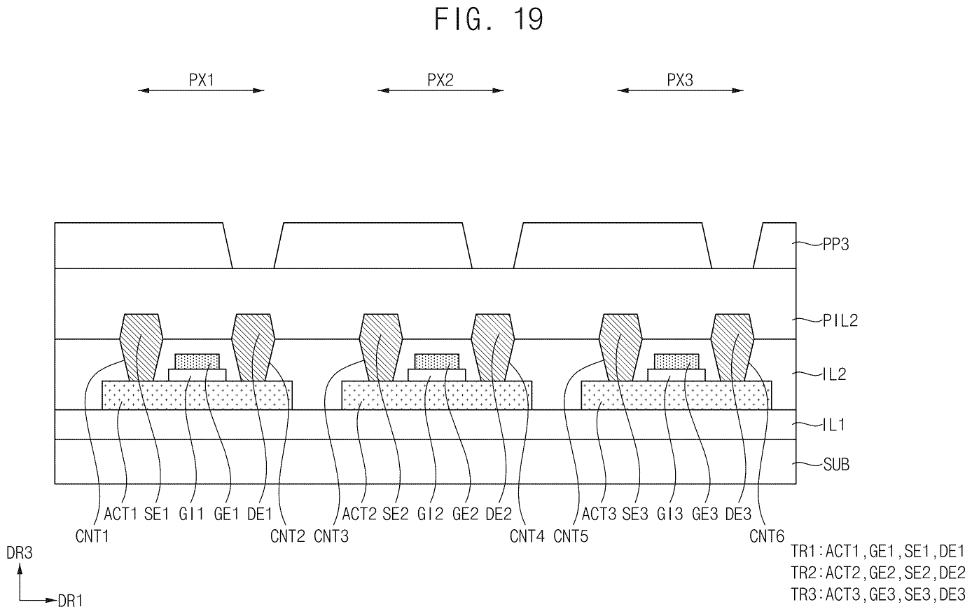

Referring to FIG. 18, a second preliminary insulating layer PIL2 may be formed on the second insulating layer IL2. The second preliminary insulating layer PIL2 may be formed to cover the first contact electrode SE1, the second contact electrode DE1, the third contact electrode SE2, the fourth contact electrode DE2, the fifth contact electrode SE3, and the sixth contact electrode DE3. For example, the second preliminary insulating layer PIL2 may be formed to cover the second portion of the first contact electrode SE1, the second portion of the second contact electrode DE1, the second portion of the third contact electrode SE2, the second portion of the fourth contact electrode DE2, the second portion of the fifth contact electrode SE3, and the second portion of the sixth contact electrode DE3. The second preliminary insulating layer PIL2 may include inorganic materials such as silicon oxide (“SiOₓ”), silicon nitride (“SiNₓ”), silicon carbide (“SiCₓ”), silicon oxynitride (“SiOₓN_{y}”), silicon oxycarbide (“SiOₓC_{y}”), and/or the like. These materials may be used alone or in combination with each other.

A third photoresist layer PL3 may be formed on the second preliminary insulating layer PIL2. A mask may be placed on the third photoresist layer PL3. The mask may include a light-transmitting area and a blocking area.

The light-transmitting area may be an area of the mask through which light passes and reaches the third photoresist layer PL3. The blocking area may be an area of the mask through which light does not pass and therefore does not reach the third photoresist layer PL3. The third photoresist layer PL3 may be a positive photoresist layer or a negative photoresist layer. For convenience of explanation, a case in which the third photoresist layer PL3 is a negative photoresist layer will be described as an example.

Referring to FIGS. 18 and 19, the third photoresist layer PL3 may be subjected to an exposure process and then a development process. Accordingly, a third photoresist pattern PP3 may be formed. For example, a portion of the third photoresist layer PL3 overlapping the blocking area of the mask in the plan view may be removed.

Referring to FIGS. 19 and 20, a portion of the third preliminary insulating layer PIL3 may be removed through an etching process using the third photoresist pattern PP3. For example, a portion of the third preliminary insulating layer PIL3 may be removed through a dry etching process using the third photoresist pattern PP3. Accordingly, the third insulating layer IL3 including a seventh contact hole CNT7, an eighth contact hole CNT8, and a ninth contact hole CNT9 may be formed. The seventh contact hole CNT7, the eighth contact hole CNT8, and the ninth contact hole CNT9 may be connected to a corresponding recess of the third insulating layer IL3, to form an intermediate contact hole occupied by portions of a transistor electrode and a corresponding connection electrode.

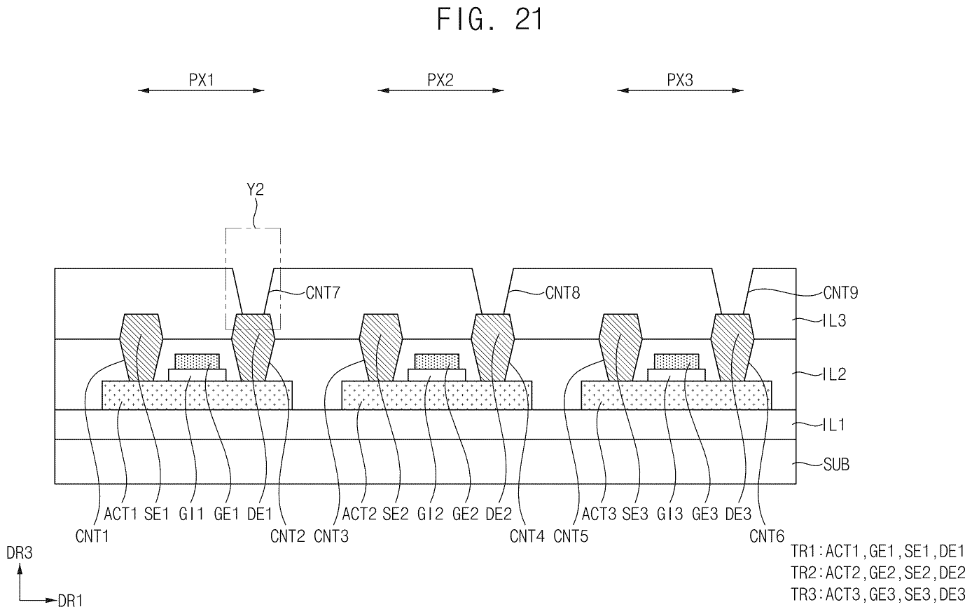

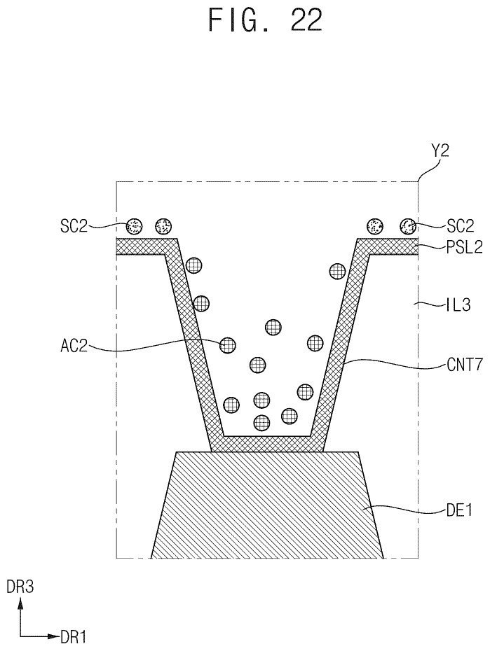

Referring to FIGS. 20 and 21, the third photoresist pattern PP3 may be removed. For example, the third photoresist pattern PP3 may be removed through a stripping process, but this disclosure is not necessarily limited thereto.

Referring to FIGS. 21 and 22, a second preliminary seed layer PSL2 may be formed on the third insulating layer IL3. The second preliminary seed layer PSL2 may be formed to fill the seventh contact hole CNT7, the eighth contact hole CNT8, and the ninth contact hole CNT9. For example, FIG. 22 may illustrate a structure in which the second preliminary seed layer PSL2 is formed to fill remaining volumes of the seventh contact hole CNT7, but this disclosure is not necessarily limited thereto, and the second preliminary seed layer PSL2 may also be formed to fill the eighth contact hole CNT8 and the ninth contact hole CNT9. For example, the second preliminary seed layer PSL2 may be continuously formed across the first pixel area PX1, the second pixel area PX2, and the third pixel area PX3. The second preliminary seed layer PSL2 may include a first layer and a second layer located on the first layer. The first layer may include titanium (“Ti”), and the second layer may include tantalum (“Ta”), but this disclosure is not necessarily limited thereto.

Referring further to FIG. 23, a second electrode layer SDL2 may be formed on the third insulating layer IL3. The second electrode layer SDL2 may be formed to fill the remaining volumes of the seventh contact hole CNT7, the eighth contact hole CNT8, and the ninth contact hole CNT9. In one or more embodiments, the second electrode layer SDL2 may be formed by performing an electroplating process on the second preliminary seed layer PSL2. In one or more embodiments, the second electrode layer SDL2 and the first electrode layer (e.g., the first electrode layer SDL1 of FIG. 13) may be formed through substantially a same method. For example, the electroplating process may be performed using a copper plating solution. The copper plating solution may include an aqueous electrolyte solution, a second accelerator AC2, and a second suppressor SC2. The aqueous electrolyte solution may include a water-soluble copper salt, the second accelerator AC2 may promote a reduction reaction of copper, and the second suppressor SC2 may suppress the reduction reaction of copper. The second accelerator AC2 and the first accelerator AC1 (e.g., the first accelerator AC1 of FIG. 12) may include substantially a same material. The second suppressor SC2 and the first suppressor SC1 (e.g., the first suppressor SC1 of FIG. 12) may include substantially a same material.

In one or more embodiments, in the electroplating process, the second accelerator AC2 may be located in an area which overlaps the seventh contact hole CNT7, the eighth contact hole CNT8, and the ninth contact hole CNT9 in the plan view, and the second suppressor SC2 may be located in an area spaced apart from (e.g., non-overlapping) the seventh contact hole CNT7, the eighth contact hole CNT8, and the ninth contact hole CNT9 in the plan view. Accordingly, a formation rate of the second electrode layer SDL2 in the seventh contact hole CNT7, the eighth contact hole CNT8, and the ninth contact hole CNT9 may be faster than a formation rate of the second electrode layer SDL2 on the third insulating layer IL3. For example, a thickness of the second electrode layer SDL2 in the seventh contact hole CNT7, the eighth contact hole CNT8, and the ninth contact hole CNT9 may be greater than a thickness of the second electrode layer SDL2 on the third insulating layer IL3.

As the second electrode layer SDL2 is formed through the electroplating process, the second electrode layer SDL2 may include a material included in the second accelerator AC2 and a material included in the second suppressor SC2. For example, the second electrode layer SDL2 may include bis-(3-sulfopropyl) disulfide (“SPS”), mercaptopropanesulfonic acid (“MPS”), 3-N, N-dimethylaminodithiocarbamoyl-1-propanesulfonic acid (“DPS”), polyethylene oxide (“PEO”), polypropylene oxide (“PPO”), polyethylene glycol (“PEG”), polypropylene glycol (“PPG”), and/or the like. These materials may be used alone or in combination with each other.

A method of forming the second electrode layer SDL2 has been described with reference to FIGS. 18, 19, 20, 21, 22, and 23. The second electrode layer SDL2 may be formed through a damascene process. For example, the second electrode layer SDL2 may be formed by performing the electroplating process after forming the third insulating layer IL3 including the seventh contact hole CNT7, the eighth contact hole CNT8, and the ninth contact hole CNT9. While not explicitly shown in FIG. 23, it will be understood that the second preliminary seed layer PSL2 is between the second electrode layer SDL2 and the underlying stacked structure defining an upper portion of the intermediate contact holes.

Referring to FIG. 24, a fourth photoresist layer PL4 may be formed on the second electrode layer SDL2. A mask may be placed on the fourth photoresist layer PL4. The mask may include a light-transmitting area and a blocking area.

The light-transmitting area may be an area of the mask through which light passes and reaches the fourth photoresist layer PL4. The blocking area may be an area of the mask through which light does not pass and therefore does not reach the fourth photoresist layer PL4. The fourth photoresist layer PL4 may be a positive photoresist layer or a negative photoresist layer. For convenience of explanation, a case in which the fourth photoresist layer PL4 is a negative photoresist layer will be described as an example.

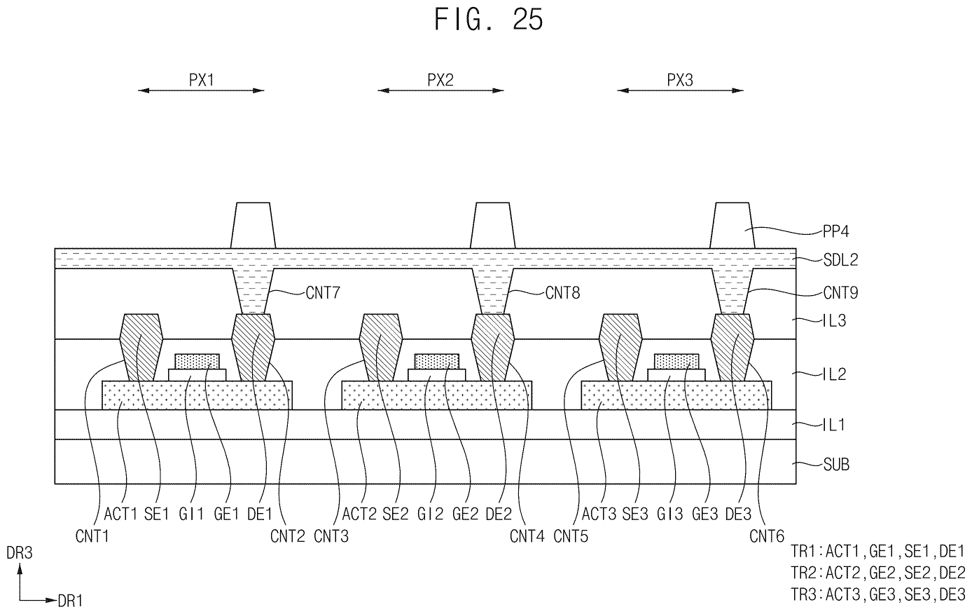

Referring to FIGS. 24 and 25, the fourth photoresist layer PL4 may be subjected to an exposure process and then a development process. Accordingly, a fourth photoresist pattern PP4 may be formed. For example, a portion of the fourth photoresist layer PL4 overlapping the blocking area of the mask in the plan view may be removed.

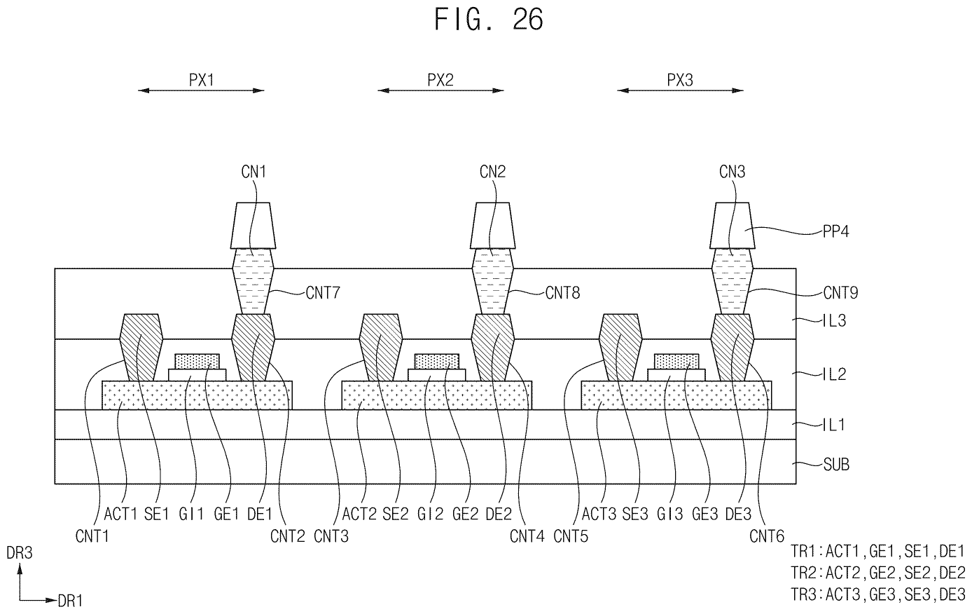

Referring to FIGS. 25 and 26, a portion of the second electrode layer SDL2 may be removed through an etching process using the fourth photoresist pattern PP4. For example, the portion of the second electrode layer SDL2 may be removed through a wet etching process using the fourth photoresist pattern PP4. For example, a portion of the second electrode layer SDL2 which is spaced apart from the fourth photoresist pattern PP4 in the plan view may be removed. For example, a portion of the second electrode layer SDL2 located on the third insulating layer IL3 may be removed through the wet etching process. The wet etching process may be an isotropic etching process. Accordingly, even a portion of the second electrode layer SDL2 located under the fourth photoresist pattern PP4 may also be removed. For example, as illustrated in FIG. 26, a seventh undercut area in which the fourth photoresist pattern PP4 and the first connection electrode CN1 are spaced apart from each other without contact may be formed on the third insulating layer IL3. In addition, an eighth undercut area in which the fourth photoresist pattern PP4 and the second connection electrode CN2 are spaced apart from each other without contact may be formed on the third insulating layer IL3. In addition, a ninth undercut area in which the fourth photoresist pattern PP4 and the third connection electrode CN3 are spaced apart from each other without contact may be formed on the third insulating layer IL3.

In one or more embodiments, at least a portion of the second preliminary seed layer (e.g., the second preliminary seed layer PSL2 of FIG. 22) may be removed through the wet etching process. For example, a portion of the second preliminary seed layer which is spaced apart from the seventh contact hole CNT7, the eighth contact hole CNT8, and the ninth contact hole CNT9 in the plan view may be removed through the wet etching process. Accordingly, the second seed layer (e.g., the second seed layer SL2 of FIG. 5) may be formed.

For example, a portion of the second electrode layer SDL2 which is spaced apart from the fourth photoresist pattern PP4 in the plan view, and a portion of the second electrode layer SDL2 located under the fourth photoresist pattern PP4, may be removed. As a result, the first connection electrode CN1, the second connection electrode CN2, and the third connection electrode CN3 may be formed.

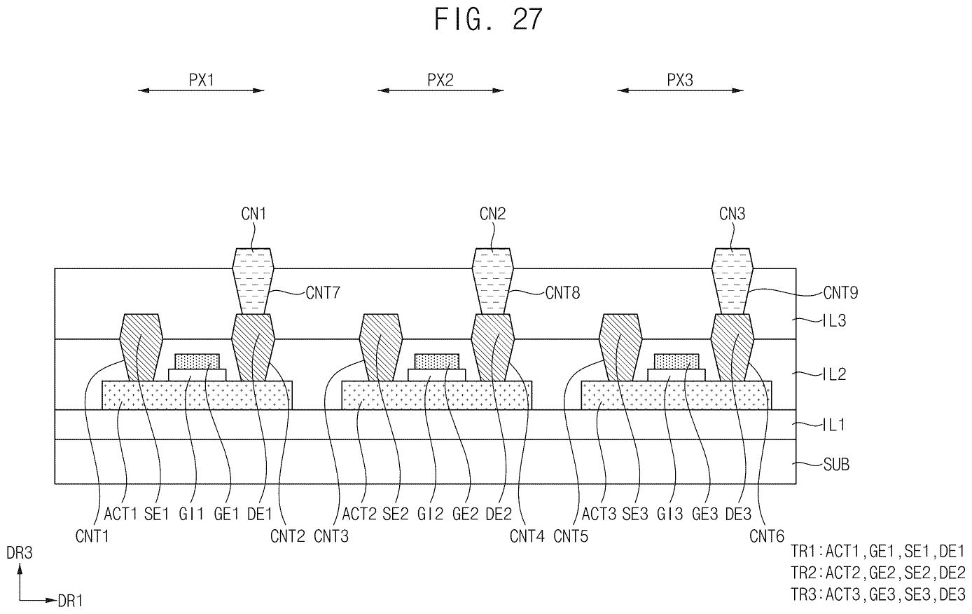

Referring to FIG. 27, the fourth photoresist pattern PP4 may be removed. For example, the fourth photoresist pattern PP4 may be removed through a stripping process, but this disclosure is not necessarily limited thereto.

Referring to FIGS. 23 and 26, the second electrode layer SDL2 may be formed to fill the seventh contact hole CNT7, the eighth contact hole CNT8, and the ninth contact hole CNT9 through the damascene process. For example, the second electrode layer SDL2 may be formed by performing the electroplating process after forming the third insulating layer IL3 including the seventh contact hole CNT7, the eighth contact hole CNT8, and the ninth contact hole CNT9. Each of a first portion (e.g., the first portion CN1-A of FIG. 5) of the first connection electrode CN1 which fills the seventh contact hole CNT7, a first portion of the second connection electrode CN2 which fills the eighth contact hole CNT8, and a first portion of the third connection electrode CN3 which fills the ninth contact hole CNT9 may be understood as being formed through the damascene process (or the electroplating process).

As the resolution of the display device increases, aspect ratio of each of the seventh contact hole CNT7, the eighth contact hole CNT8, and the ninth contact hole CNT9 may increase. According to one or more embodiments, as the first portion of the first connection electrode CN1 which fills the seventh contact hole CNT7, the first portion of the second connection electrode CN2 which fills the eighth contact hole CNT8, and the first portion of the third connection electrode CN3 which fills the ninth contact hole CNT9 are formed through the damascene process (or the electroplating process), even if the aspect ratio of each of the seventh contact hole CNT7, the eighth contact hole CNT8, and the ninth contact hole CNT9 increases, the first portions of the first connection electrode CN1, the first portion of the second connection electrode CN2, and the first portion of the third connection electrode CN3 may not include skew, seam, void, and/or the like. Accordingly, the first connection electrode CN1, the second connection electrode CN2, and the third connection electrode CN3 suitable for a high-resolution display device may be formed.

In addition, a portion of the second electrode layer SDL2 located above the third insulating layer IL3 may be removed through the wet etching process. Each of the second portion (e.g., the second portion CN1-B of FIG. 5) of the first connection electrode CN1, the second portion of the second connection electrode CN2, and the second portion of the third connection electrode CN3 may be understood as being formed through the damascene process (or the electroplating process) and the wet etching process. Accordingly, each of the first connection electrode CN1, the second connection electrode CN2, and the third connection electrode CN3 may be formed without a chemical mechanical polishing process. Accordingly, each of the first connection electrode CN1, the second connection electrode CN2, and the third connection electrode CN3 may be formed through the damascene process (or the electroplating process) and the wet etching process without requiring equipment for performing the chemical mechanical polishing process. Accordingly, manufacturing cost and manufacturing time of the display device may be reduced.

In summary, the first connection electrode CN1, the second connection electrode CN2, and the third connection electrode CN3, which are suitable for a high-resolution display device, may be formed through the damascene process (or the electroplating process) and the wet etching process with reduced manufacturing cost and manufacturing time.

In an embodiment, a connection electrode (or a transistor electrode) may be considered as a multilayer stack including a first seed layer SL1, the transistor electrode (DE), a second seed layer SL2 and a connection electrode (CN) in order from the active layer. Such connection electrode is extended through a continuous contact hole (CNT2, CNT4 or CNT6, recess in third insulating layer IL3 and CNT 7, CNT8 or CNT9, respectively).

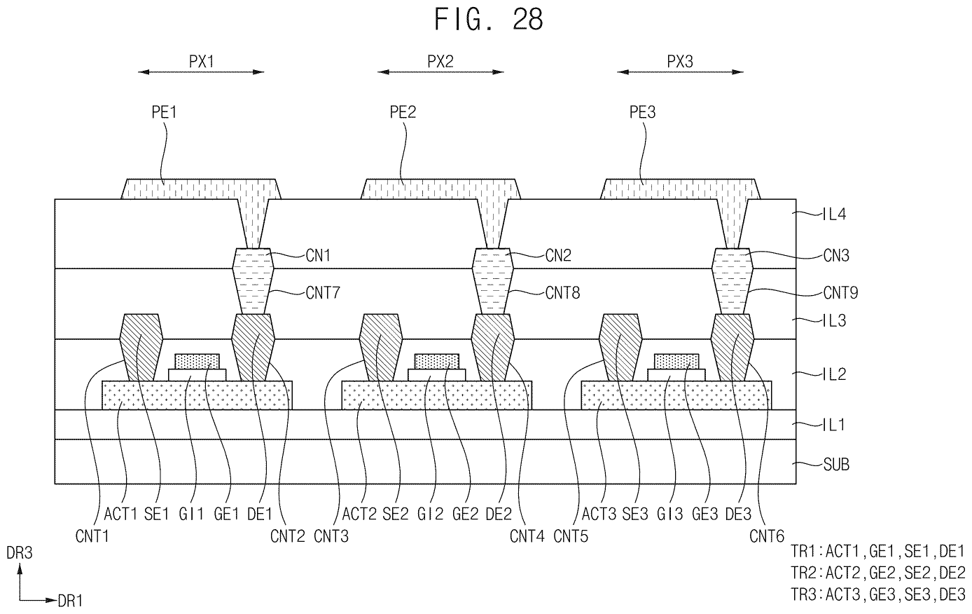

Referring to FIG. 28, the fourth insulating layer IL4 may be formed on the third insulating layer IL3. The fourth insulating layer IL4 may be formed to cover at least a portion of each of the first connection electrode CN1, the second connection electrode CN2, and the third connection electrode CN3. The fourth insulating layer IL4 may include an organic material such as phenolic resin, polyacrylates resin, polyimides resin, polyamides resin, siloxane resin, epoxy resin, and/or the like. These materials may be used alone or in combination with each other.

The first pixel electrode PE1, the second pixel electrode PE2, and the third pixel electrode PE3 may be formed on the fourth insulating layer IL4. The first pixel electrode PE1 may be formed in the first pixel area PX1, the second pixel electrode PE2 may be formed in the second pixel area PX2, and the third pixel electrode PE3 may be formed in the third pixel area PX3. The first pixel electrode PE1 may be formed to be connected to the first connection electrode CN1 through a contact hole included in the fourth insulating layer IL4. The second pixel electrode PE2 may be formed to be connected to the second connection electrode CN2 through a contact hole included in the fourth insulating layer IL4. The third pixel electrode PE3 may be formed to be connected to the third connection electrode CN3 through a contact hole included in the fourth insulating layer IL4. The contact holes in the fourth insulating layer IL4 may be connected to a corresponding recess of the fourth insulating layer IL4, to form an upper contact hole occupied by portions of a pixel electrode and an upper portion of a corresponding connection electrode.

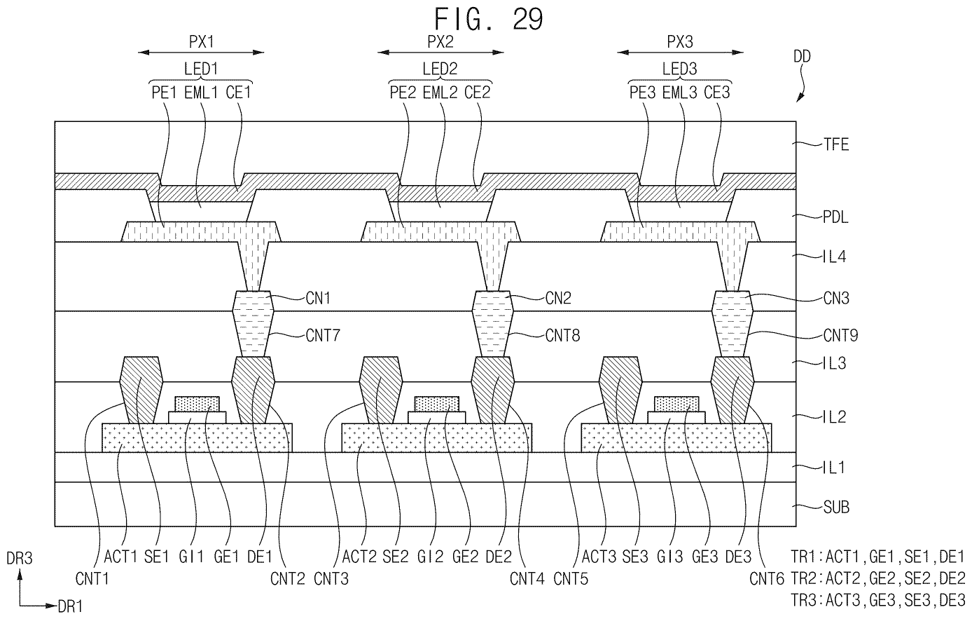

Referring to FIG. 29, the pixel defining layer PDL may be formed on the fourth insulating layer IL4. The pixel defining layer PDL may be formed to cover a side of the first pixel electrode PE1. In addition, the pixel defining layer PDL may be formed to cover a side of the second pixel electrode PE2. In addition, the pixel defining layer PDL may be formed to cover a side of the third pixel electrode PE3. The pixel defining layer PDL may include an organic material such as epoxy resin, siloxane resin, and/or the like. These materials may be used alone or in combination with each other. In one or more embodiments, the pixel defining layer PDL may further include a light-blocking material containing a black pigment, a black dye, and/or the like.

The first light-emitting layer EML1 may be formed on the first pixel electrode PE1. The first light-emitting layer EML1 may be formed in the first pixel area PX1. The second light-emitting layer EML2 may be formed on the second pixel electrode PE2. The second light-emitting layer EML2 may be formed in the second pixel area PX2. The third light-emitting layer EML3 may be formed on the third pixel electrode PE3. The third light-emitting layer EML3 may be formed in the third pixel area PX3. Each of the first light-emitting layer EML1, the second light-emitting layer EML2, and the third light-emitting layer EML3 may include an organic material which emits light of a selected color.

The first common electrode CE1 may be formed on the first light-emitting layer EML1. The first common electrode CE1 may be formed in the first pixel area PX1. The second common electrode CE2 may be formed on the second light-emitting layer EML2. The second common electrode CE2 may be formed in the second pixel area PX2. The third common electrode CE3 may be formed on the third light-emitting layer EML3. The third common electrode CE3 may be formed in the third pixel area PX3. Each of the first common electrode CE1, the second common electrode CE2, and the third common electrode CE3 may include a metal, an alloy, a metal nitride, a conductive metal oxide, a transparent conductive material, and/or the like. These materials may be used alone or in combination with each other.

The encapsulation layer TFE may be formed on the first common electrode CE1, the second common electrode CE2, and the third common electrode CE3. The encapsulation layer TFE may include at least one inorganic layer and at least one organic layer. For example, the inorganic layer may include silicon oxide, silicon nitride, silicon oxynitride, and/or the like. These materials may be used alone or in combination with each other. The organic layer may include a polymer cured material such as polyacrylate.

The display device (e.g., the display device DD of FIG. 1) according to embodiments may be applied to various electronic devices. An electronic device according to embodiments may include the above-described display device, and may further include a module or device having other additional functions in addition to the display device.

In an embodiment, a method of providing a display device DD includes providing a first insulating layer including a contact hole defined therein, providing an electrode layer (like SDL1 or SDL2) on the first insulating layer and filling the contact hole, patterning the electrode layer to form a contact electrode (like SE, DE or CN) in the contact hole, providing a second insulating layer on the first insulating layer and covering the contact electrode, and providing a light-emitting element which is on the second insulating layer and connected to the contact electrode.

The providing of the electrode layer may include an electroplating process to form an electroplating layer (like SDL1 or SDL2) which defines the contact electrode. The electroplating process may include providing a copper plating solution having an aqueous electrolyte solution, an accelerator and a suppressor. The electroplating process may further include the accelerator of the copper plating solution overlapping the contact hole, and the suppressor on the first insulating layer and non-overlapping the contact hole.

The method may further include providing an electroplating preliminary seed layer on the first insulating layer and filling the contact hole, and patterning the electroplating preliminary seed layer through a wet etching process to remove a portion of the electroplating preliminary seed layer which is adjacent to the contact hole and forming an electroplating seed layer in the contact hole.

The patterning of the electrode layer may include removing a portion of the electrode layer which is on the first insulating layer and adjacent to the contact hole, through a wet etching process.

The method may further include providing an active pattern of a transistor connected to the light-emitting element. Here the first insulating layer may be on the active pattern and the contact hole may expose the active pattern to outside the first insulating layer. The contact electrode may electrically connect the active pattern of the transistor to the light-emitting element.

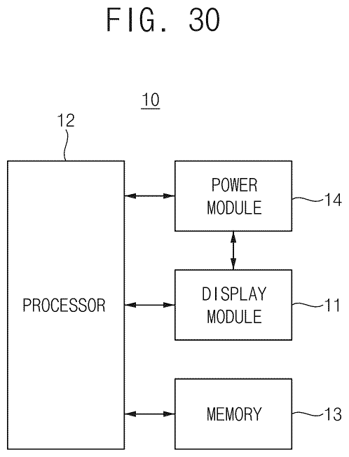

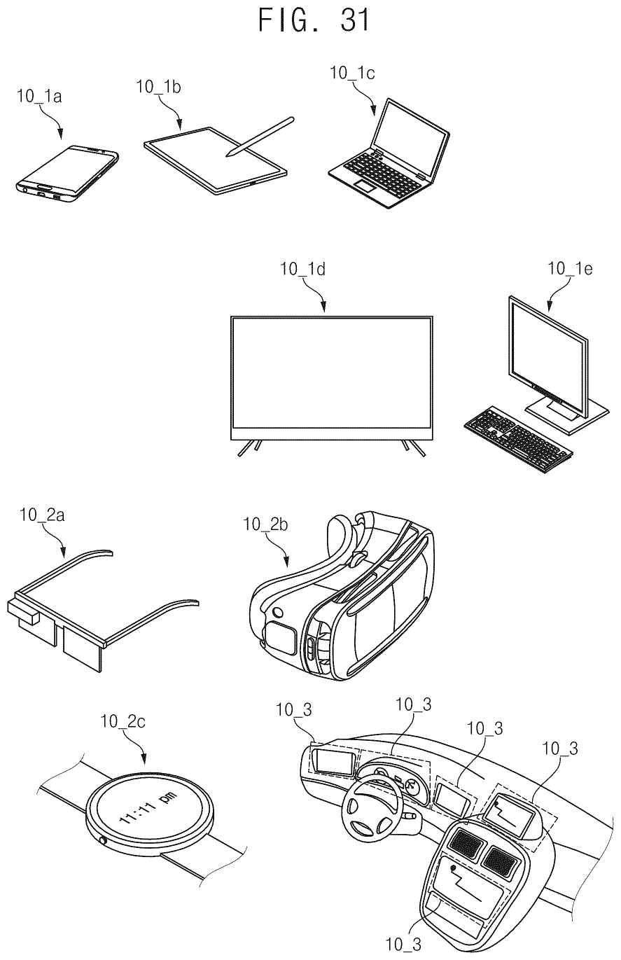

FIG. 30 is a block diagram illustrating an electronic device according to embodiments.

Referring to FIG. 30, an electronic device 10 according to embodiments may include a display module 11, a processor 12, a memory 13, and a power module 14.

The processor 12 may include at least one of a central processing unit (“CPU”), an application processor (“AP”), a graphic processing unit (“GPU”), a communication processor (“CP”), an image signal processor (“ISP”), and a controller.

Data information necessary for operation of the processor 12 or the display module 11 may be stored in the memory 13. When the processor 12 executes an application stored in the memory 13, an image data signal and/or an input control signal is transmitted to the display module 11, and the display module 11 may process received signal and output image information through a display screen.

The power module 14 may include a power supply module such as a power adapter or a battery device, and a power conversion module which converts power supplied by the power supply module to generate power required for operation of the electronic device 10.

At least one of components of the electronic device 10 described above may be included in the display device according to the above-described embodiments. In addition, some of individual modules functionally included in one module may be included in the display device, and others may be provided separately from the display device. For example, the display device may include the display module 11, and the processor 12, the memory 13, and the power module 14 may be provided in form of another device in the electronic device 10 other than the display device.

FIG. 31 is a schematic diagram of electronic devices according to various embodiments.

Referring to FIG. 31, various electronic devices to which display devices according to embodiments are applied may include not only electronic devices for image display such as a smartphone 10_1a, a tablet personal computer (PC) 10_1b, a laptop 10_1c, a television (TV) 10_1d, a desk monitor 10_1e, and/or the like, but also wearable electronic devices including display modules such as a smart glass 10_2a, a head mounted display 10_2b, a smart watch 10_2c, and/or the like, vehicle electronic device 10_3 including display modules such as a vehicle's instrument panel, a center fascia, a center information display (“CID”) located on a dashboard, a room mirror display, and/or the like.

In an embodiment, an electronic device includes a display device DD and a memory (or processor, etc.) connected to the display device DD and configured to store data information. The display device DD includes a first insulating layer (like IL3 or IL3) in which a contact hole is defined, a second insulating layer (like IL3 or IL4) on the first insulating layer, a light-emitting element on the second insulating layer, and a contact electrode (like SE, DE or CN) connected to the light-emitting element. The contact electrode includes a first portion in the contact hole, the first portion extended out of the contact hole and into the second insulating layer to define a second portion of the contact electrode, and a width of the second portion decreasing in a direction from the first insulating layer to the second insulating layer.

The present disclosure can be applied to various display devices. For example, the present disclosure is applicable to various display devices such as display devices for vehicles, ships and aircraft, portable communication devices, display devices for exhibition or information transmission, medical display devices, and the like.

The foregoing is illustrative of embodiments and is not to be construed as limiting thereof. Although a few embodiments have been described, those skilled in the art will readily appreciate that many modifications are possible in the embodiments without materially departing from the novel teachings and advantages of the present inventive concept. Accordingly, all such modifications are intended to be included within the scope of the present inventive concept as defined in the claims. Therefore, it is to be understood that the foregoing is illustrative of various embodiments and is not to be construed as limited to the specific embodiments disclosed, and that modifications to the disclosed embodiments, as well as other embodiments, are intended to be included within the scope of the appended claims.

What is claimed is:

1. A display device comprising:
a first insulating layer on a substrate, the first insulating layer including a first contact hole;
a first contact electrode including a first portion filling the first contact hole a second portion located on the first portion, wherein the second portion has a width that decreases as a distance between the first portion and the second portion increases;
a second insulating layer covering the second portion of the first contact electrode; and
a light-emitting element on the second insulating layer.

2. The display device of claim 1, wherein the first portion of the first contact electrode and the second portion of the first contact electrode are in direct contact with each other.

3. The display device of claim 1, wherein at least a portion of a side surface of the second portion of the first contact electrode includes a curved surface.

4. The display device of claim 1, wherein a width of an upper surface of the second portion of the first contact electrode is smaller than a width of the first contact hole.

5. The display device of claim 1, wherein a width of the first portion of the first contact electrode increases as a distance between the first portion and the second portion decreases.

6. The display device of claim 1, further comprising:
a seed layer filling the first contact hole and covering a side surface of the first contact electrode and a lower surface of the first contact electrode.

7. The display device of claim 6, wherein the seed layer includes,
a first layer having a thickness equal to or greater than about 100 angstroms and equal to or less than about 200 angstroms; and
a second layer located on the first layer and having a thickness equal to or greater than about 300 angstroms and equal to or less than about 3000 angstroms.

8. The display device of claim 1, wherein the first contact electrode includes at least one selected from bis-(3-sulfopropyl) disulfide (“SPS”), mercaptopropanesulfonic acid (“MPS”), and 3-N, N-dimethylaminodithiocarbamoyl-1-propanesulfonic acid (“DPS”).

9. The display device of claim 1, wherein the first insulating layer further includes a second contact hole, and
further comprising:
a second contact electrode including a first portion filling the second contact hole and a second portion having a width decreasing as a distance between the first portion filling the second contact hole and the second portion of the second contact electrode increases.

10. The display device of claim 9, wherein the second insulating layer includes a third contact hole exposing at least a portion of the second portion of the second contact electrode, and
further comprising:
a connection electrode including a first portion filling the third contact hole and a second portion connected to the light-emitting element and having a width that decreases as a distance between the light-emitting element and the second portion of the connection electrode decreases.

11. The display device of claim 1, further comprising:
an active pattern located on the substrate, and
wherein the first insulating layer covers the active pattern, and the first contact hole exposes at least a portion of the active pattern.

12. A method of manufacturing a display device, the method comprising:
forming a first insulating layer including a contact hole on a substrate;
forming an electrode layer located on the first insulating layer and filling the contact hole;
forming a photoresist pattern on the electrode layer;
removing at least a portion of the electrode layer to form a contact electrode;
forming a second insulating layer covering at least a portion of the contact electrode; and
forming a light-emitting element on the second insulating layer.

13. The method of claim 12, wherein the forming of the electrode layer is performed through an electroplating process.

14. The method of claim 13, wherein the electroplating process is performed using a copper plating solution, and the copper plating solution includes an aqueous electrolyte solution, an accelerator, and a suppressor.

15. The method of claim 14, wherein the accelerator is located in a portion overlapping the contact hole in a plan view, and the suppressor is located in a portion spaced apart from the contact hole in the plan view.

16. The method of claim 12, further comprising:
forming a preliminary seed layer located on the first insulating layer and filling the contact hole.

17. The method of claim 16, wherein at least a portion of the preliminary seed layer is removed through a wet etching process to form a seed layer.

18. The method of claim 12, wherein the removing of at least the portion of the electrode layer includes removing at least a portion of the electrode layer located on the first insulating layer through a wet etching process.

19. The method of claim 12, further comprising:
forming an active pattern on the substrate, and
wherein the first insulating layer covers the active pattern, and the contact hole exposes at least a portion of the active pattern.

20. An electronic device comprising:
a first insulating layer on a substrate, the first insulating layer including a first contact hole;
a first contact electrode including a first portion filling the first contact hole a second portion located on the first portion, wherein the second portion has a width that decreases as a distance between the first portion and the second portion increases;
a second insulating layer covering the second portion of the first contact electrode;
a light-emitting element on the second insulating layer; and
a memory configured to store data information.
